(19) United States
(12) Patent Application Publication
(10) Pub. No.: US 2025/0160102 A1
(43) Pub. Date: May 15, 2025

(54) Light-Emitting Substrate and Manufacturing Method Therefor, Backlight Module, and Display Apparatus

(71) Applicants: Hefei BOE Ruisheng Technology Co., Ltd., Hefei, Anhui (CN); BOE TECHNOLOGY GROUP CO., LTD., Chaoyang District, Beijing (CN)

(72) Inventors: Hai Tang, Beijing (CN); Xiaolin Geng, Beijing (CN); Xing Liu, Beijing (CN); Liang Gao, Beijing (CN); Ming Zhai, Beijing (CN)

(21) Appl. No.: 18/839,799

(22) PCT Filed: Aug. 3, 2022
(86) PCT No.: PCT/CN2022/109938

§ 371 Date: Aug. 20, 2024

(51) Int. Cl. H10H 29/856; H01L 25/075; H10H 29/14

(52) U.S. Cl. CPC H10H 29/856; H01L 25/0753; H10H 29/142

(57) ABSTRACT

A light-emitting substrate includes a substrate, a plurality of light-emitting devices and a reflective layer that are disposed on a side of the substrate; the reflective layer has a plurality of openings, the plurality of openings include a plurality of first openings, and a light-emitting device is located in a first opening; the reflective layer includes a plurality of first reflective portions and a second reflective portion connecting any two adjacent first reflective portions; a first reflective portion, corresponding to the light-emitting device, is located on at least one side of the light-emitting device; a thickness of the first reflective portion is less than a thickness of the second reflective portion.

### CROSS-REFERENCE TO RELATED APPLICATION

This application is a national phase entry of International Patent Application No. PCT/CN2022/109938, filed on Aug. 3, 2022, which is incorporated by reference in its entirety.

### BACKGROUND OF THE INVENTION

### Field of the Invention

The present disclosure relates to the field of display technologies, and in particular, to a light-emitting substrate and a manufacturing method therefor, a backlight module, and a display apparatus.

### Description of Related Art

Mini light-emitting diodes (mini LEDs) and micro light-emitting diodes (micro LEDs) have been applied to the fields of medium-sized displays such as micro displays, mobile phones and televisions and large-sized displays such as screens in cinemas due to their advantages of self-luminescence, high efficiency, high luminance, high reliability, energy saving, fast response speed and the like.

### SUMMARY OF THE INVENTION

In an aspect, a light-emitting substrate is provided. The light-emitting substrate includes a substrate, a plurality of light-emitting devices and a reflective layer that are disposed on a side of the substrate. The reflective layer has a plurality of openings, the plurality of openings include a plurality of first openings, and a light-emitting device of the plurality of light-emitting devices is located in a first opening of the plurality of first openings. The reflective layer includes a plurality of first reflective parts and a second reflective portion connecting any two adjacent first reflective portions; a first reflective portion, corresponding to the light-emitting device, of the plurality of first reflective portions is located on at least one side of the light-emitting device. A thickness of the first reflective portion is less than a thickness of the second reflective portion.

In some embodiments, the first reflective portion is located on two opposite sides of the light-emitting device, or the first reflective portion surrounds the light-emitting device.

In some embodiments, in a case where the first reflective portion is located on the two opposite sides of the light-emitting device, and an orthographic projection of the light-emitting device on the substrate is in a shape of a rectangle, the first reflective portion is located on sides of two long sides of the rectangle.

In some embodiments, at least one side wall of the light-emitting device and the corresponding first reflective portion have a first gap therebetween.

In some embodiments, a width of the first gap is less than or equal to 150 μm.

In some embodiments, at least one side wall of the light-emitting device is in contact with the corresponding first reflective portion.

In some embodiments, the thickness of the first reflective portion is positively correlated with a distance, in a direction passing through a center of the light-emitting device and perpendicular to a side wall of the light-emitting device, between the first reflective portion and the center of the light-emitting device; the first reflective portion includes a bottom surface and a top surface that are opposite to each other, the bottom surface is in contact with the substrate, and an angle between the top surface and a plane where the substrate is located is an acute angle.

In some embodiments, a minimum thickness of the first reflective portion is less than 60 μm.

In some embodiments, the thickness of the first reflective portion is positively correlated with a distance, in a direction passing through a center of the light-emitting device and perpendicular to a side wall of the light-emitting device, between the first reflective portion and the center of the light-emitting device. The first reflective portion includes a bottom surface and a top surface that are opposite to each other; at least portion of the bottom surface is not in contact with the substrate, and an angle between the at least portion of the bottom surface and a plane where the substrate is located is an acute angle; the top surface parallel to or substantially parallel to the plane where the substrate is located.

In some embodiments, in the direction passing through the center of the light-emitting device and perpendicular to the side wall of the light-emitting device, a dimension of a portion of the first reflective portion that is not in contact with the substrate is less than 20 μm.

In some embodiments, a surface of the second reflective portion away from the substrate is a flat surface or an approximately flat surface.

In some embodiments, the second reflective portion includes a plurality of protruding structures, and a protruding structure of the plurality of protruding structures has a cambered surface on a side away from the substrate.

In some embodiments, the plurality of protruding structures include a plurality of first protruding structures and a plurality of second protruding structures. The plurality of first protruding structures each extend in a first direction and are arranged in rows in a second direction. The plurality of second protruding structures each extend in the first direction and are arranged in rows in the second direction, or the plurality of second protruding structures each extend in the second direction and are arranged in rows in the first direction. The first direction intersects with the second direction. A dimension of a first protruding structure of the plurality of first protruding structures in the second direction is same as a dimension of a second protruding structure of the plurality of second protruding structures in an arrangement direction of the plurality of second protruding structures.

In some embodiments, the plurality of protruding structures further includes a third protruding structure located between two adjacent first protruding structures, the third protruding structure extends in the first direction. A dimension of the third protruding structure in the second direction is less than a dimension of the first protruding structure in the second direction.

In some embodiments, in a case where the first reflective portion surrounds the light-emitting device, the reflective layer further includes a third reflective portion located between the first reflective portion and the second reflective portion; the second reflective portion is connected to the first reflective portion through the third reflective portion, the third reflective portion surrounds the first reflective portion, and a thickness of the third reflective portion is less than the thickness of the first reflective portion.

In some embodiments, the plurality of light-emitting devices are arranged in columns in a first direction and arranged in rows in a second direction, the first direction intersects with the second direction. In a case where the first reflective portion surrounds the light-emitting device and an orthographic projection of the light-emitting device on the substrate is in a shape of a rectangle, the light-emitting device includes a first side wall, a second side wall, a third side wall and a fourth side wall that are connected in sequence; the first side wall is opposite to the third side wall and extends in the first direction; the second side wall is opposite to the fourth side wall and extends in the second direction; the first reflective portion includes a first reflective sub-portion located on a side of the first side wall, a second reflective sub-portion located on a side of the second side wall, a third reflective sub-portion located on a side of the third side wall, and a fourth reflective sub-portion located on a side of the fourth side wall. A plurality of first reflective sub-portions located on a side of first side walls of light-emitting devices in a row are connected to form a one-piece structure. A plurality of second reflective sub-portions located on a side of second side walls of the light-emitting devices in the row are connected to form a one-piece structure. A plurality of third reflective sub-portions located on a side of third side walls of the light-emitting devices in the row are connected to form a one-piece structure. A plurality of fourth reflective sub-portions located on a side of fourth side walls of the light-emitting devices in the row are connected to form a one-piece structure.

In some embodiments, the light-emitting substrate further includes a plurality of driver chips disposed on a side of the substrate and located on a same side of the substrate as the plurality of light-emitting devices. A driver chip of the plurality of driver chips is electrically connected to at least one light-emitting device of the plurality of light-emitting devices, and the driver chip is configured to drive the at least one light-emitting device to emit light. The plurality of openings further include a plurality of second openings. The driver chip is located in a second opening, and a first reflective portion, corresponding to the driver chip, of the plurality of first reflective portions is located on at least one side of the driver chip.

In some embodiments, at least one side wall of the driver chip is in contact with the corresponding first reflective portion, and/or the at least one side wall of the driver chip and the corresponding first reflective portion have a second gap therebetween.

In some embodiments, the light-emitting substrate further includes a plurality of driver chips disposed on a side of the substrate and located on a same side of the substrate as the plurality of light-emitting devices. A driver chip is electrically connected to at least one light-emitting device, and the driver chip is configured to drive the at least one light-emitting device to emit light. An orthographic projection of at least one driver chip on the substrate is located within an orthographic projection of the reflective layer on the substrate.

In another aspect, a manufacturing method for a light-emitting substrate includes: providing a substrate; fixing a plurality of light-emitting devices on the substrate by using a flux; cleaning a portion of the substrate located around each light-emitting device; forming a reflective layer on the substrate by using a three dimensional (3D) printing process. The reflective layer has a plurality of openings, the plurality of openings include a plurality of first openings, a light-emitting device of the plurality of light-emitting devices is located in a first opening of the plurality of first openings; the reflective layer includes a plurality of first reflective portions and a second reflective portion connecting any two adjacent first reflective portions; a first reflective portion, corresponding to the light-emitting device, of the plurality of first reflective portion is located on at least one side of the light-emitting device; a thickness of the first reflective portion is less than a thickness of the second reflective portion.

In some embodiments, the plurality of light-emitting devices are arranged in columns in a first direction and arranged in rows in a second direction, the first direction intersects with the second direction. The substrate has a plurality of first printing regions and a plurality of second printing regions; at least one second printing region of the plurality of second printing regions is disposed between two adjacent first printing regions, and a row of light-emitting devices is located in a first printing region of the plurality of first printing regions. The first printing region includes a plurality of first printing sub-regions arranged at intervals in the first direction, and a first printing sub-region of the plurality of first printing sub-regions is located on at least one side of a corresponding light-emitting device of the plurality of light-emitting devices. Forming the reflective layer on the substrate by using the 3D printing process includes: forming a first reflective pattern in each first printing sub-region by using a printing process in a surrounding manner, the first reflective pattern forming a first reflective portion of the reflective layer; forming a second reflective pattern in a region in each first printing region except for the first printing sub-regions by using a printing process in a dotted-line manner; and forming a third reflective pattern in each second printing region by using a printing process in a straight-line manner, a first reflective pattern around each light-emitting device defining a first opening, or a first reflective pattern and at least one of a second reflective pattern and a third reflective pattern around each light-emitting device defining a first opening; wherein at least one side wall of the light-emitting device and the corresponding first reflective portion have a first gap therebetween, and/or at least one side wall of the light-emitting device is in contact with the corresponding first reflective portion.

In some embodiments, forming the first reflective pattern in each first printing sub-region includes: forming a plurality of first reflective sub-patterns in each first printing sub-region sequentially by using the printing process in a surrounding manner. The plurality of first reflective sub-patterns are sequentially arranged in a direction away from the light-emitting device, and two adjacent first reflective sub-patterns partially overlap; the plurality of first reflective sub-patterns form the first reflective pattern.

In some embodiments, the substrate further has a plurality of third printing regions, and the third printing regions are each located between a first printing region and a second printing region. After forming the first reflective pattern in each first printing sub-region by using the printing process in a surrounding manner, the manufacturing method further includes: forming a fourth reflective pattern in each third printing region by using a printing process in a straight-line manner, all second reflective patterns, all third reflective patterns and all fourth reflective patterns forming the second reflective portion of the reflective layer. The second reflective pattern, the third reflective pattern and the fourth reflective pattern have a same thickness. A thickness of the first reflective pattern is less than a thickness of the second reflective pattern.

In some embodiments, the plurality of light-emitting devices are arranged in columns in a first direction and arranged in rows in a second direction; the first direction intersects with the second direction. The substrate has a plurality of fourth printing region each extending in the first direction, a plurality of fifth printing regions each extending in the second direction and a plurality of sixth printing regions. Two opposite sides of each row of light-emitting devices are each provided with a fourth printing region of the plurality of fourth printing region; two opposite sides of each column of light-emitting devices are each provided with a fifth printing region of the plurality of fifth printing regions; a region between any two adjacent light-emitting devices excluding fourth printing regions and fifth printing regions between the any two adjacent light-emitting devices is provided with a sixth printing region. Forming the reflective layer on the substrate by using the 3D printing process includes: by using a printing process, printing a reflective material in each fourth printing region, and printing a reflective material in each fifth printing region; performing a pre-curing process on the reflective material in each fourth printing region to form a fifth reflective pattern, and performing a pre-curing process on the reflective material in each fifth printing region to form a sixth reflective pattern; fifth reflective patterns and sixth reflective patterns around each light-emitting device defining a first opening and forming a first reflective portion; and forming a seventh reflective sub-pattern in each sixth printing region by using a printing process in a quantification manner, and performing a levelling process and a pre-curing process on the seventh reflective sub-pattern to form a seventh reflective pattern.

In some embodiments, the plurality of light-emitting devices are arranged in columns in a first direction and arranged in rows in a second direction. The substrate has a plurality of seventh printing regions and an eighth printing region; a seventh printing region surrounds a light-emitting device, and the eighth printing region is located between any two adjacent seventh printing regions. Forming the reflective layer on the substrate by using the 3D printing process includes: printing a reflective material in each seventh printing region by using a printing process in a surrounding manner, and performing a pre-curing process on the reflective material in each seventh printing region to form an eighth reflective pattern, the eighth reflective pattern forming a first reflective portion and a portion of a third reflective portion of the reflective layer; and spraying a reflective material quantitatively in the eighth printing region by using a quantitative spraying process, and performing a levelling process and a pre-curing process on the reflective material in the eighth printing region to form a ninth reflective pattern, the ninth reflective pattern forming the second reflective portion and another portion of the third reflective portion of the reflective layer. The second reflective portion is connected to the first reflective portion through the third reflective portion; the third reflective portion surrounds the first reflective portion, and a thickness of the third reflective portion is less than the thickness of the first reflective portion.

In some embodiments, before forming the reflective layer on the substrate by using the 3D printing process, the manufacturing method further includes: forming a sacrificial layer on a side of the plurality of light-emitting devices away from the substrate, the sacrificial layer including a plurality of sacrificial patterns, and a sacrificial pattern of the plurality of sacrificial patterns covering a side wall and a top wall of a light-emitting device of the plurality of light-emitting devices. Forming the reflective layer on the substrate by using the 3D printing process includes: forming a reflective film on the substrate by using the 3D printing process, the reflective film being in contact with side walls of the sacrificial patterns, and an orthographic projection of the reflective film on the substrate being non-overlapping with orthographic projections of the light-emitting devices on the substrate; performing a levelling process and a pre-curing process on the reflective film to form the reflective layer; and removing the sacrificial layer.

In some embodiments, before forming the reflective layer on the substrate by using the 3D printing process, the manufacturing method further includes: forming a protective layer on a side of the light-emitting devices away from the substrate by using a dispensing process, the protective layer including a plurality of protective patterns, and a protective pattern covering a side wall and a top wall of a light-emitting device. Forming the reflective layer on the substrate by using the 3D printing process includes: forming a reflective film on the substrate by using the 3D printing process, the reflective film being in contact with side walls of the protective patterns, and an orthographic projection of the reflective film on the substrate is non-overlapping with orthographic projections of the light-emitting devices on the substrate; and performing a levelling process and a pre-curing process on the reflective film to form the reflective layer.

In yet another aspect, a backlight module is provided. The backlight module includes: the light-emitting substrate according to any of the above embodiments, and an optical film disposed on a light exit side of the light-substrate.

In yet another aspect, a display apparatus is provided. The display apparatus includes: the backlight module according to any of the above embodiments, an array substrate located on a light exit side of the backlight module, and a color filter substrate located on a side of the array substrate away from the backlight module.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings to be described below may be regarded as schematic diagrams, but are not limitations on actual sizes of products and actual processes of methods to which the embodiments of the present disclosure relate.

FIG. 1 is a structural diagram of a display apparatus, in accordance with some embodiments of the present disclosure;

FIG. 2 is a structural diagram of a backlight module, in accordance with some embodiments of the present disclosure;

FIG. 3 is a structural diagram of a light-emitting substrate, in accordance with some embodiments of the present disclosure;

FIG. 4 is a structural diagram of another light-emitting substrate, in accordance with some embodiments of the present disclosure;

FIGS. 5a to 5b are each a schematic diagram of flux residue appearing on a light-emitting substrate, in accordance with an implementation;

FIGS. 5c and 5d are each a schematic diagram of repel phenomenon appearing on a light-emitting substrate, in accordance with another implementation;

FIG. 6a is a diagram showing steps of a manufacturing method for a light-emitting substrate, in accordance with some embodiments of the present disclosure;

FIGS. 6b to 6e are diagrams illustrating a manufacturing process for a light-emitting substrate, in accordance with some embodiments of the present disclosure;

FIG. 7 is a schematic diagram showing an operation process of a three dimensional (3D) printing device, in accordance with some embodiments of the present disclosure;

FIG. 8a is a structural diagram showing light exit paths of a light-emitting device in a light-emitting device, in accordance with some embodiments of the present disclosure;

FIG. 8b is a structural diagram showing light exit paths of another light-emitting device in a light-emitting device, in accordance with some embodiments of the present disclosure;

FIG. 8c is a structural diagram showing light exit paths of yet another light-emitting device in a light-emitting device, in accordance with some embodiments of the present disclosure;

FIG. 9a is a diagram showing a relative positional relationship between different printing regions and light-emitting devices on a substrate, in accordance with some embodiments of the present disclosure;

FIG. 9b is a diagram showing steps of a manufacturing method for another light-emitting substrate, in accordance with some embodiments of the present disclosure;

FIGS. 9c to 9e are diagrams illustrating a manufacturing process for another light-emitting substrate, in accordance with some embodiments of the present disclosure;

FIG. 9f is a partial enlarged view of the BB region in FIG. 9c;

FIG. 9g is another partial enlarged view of the BB region in FIG. 9c;

FIG. 10a is a diagram illustrating a manufacturing process for yet another light-emitting substrate, in accordance with some embodiments;

FIG. 10b is a diagram illustrating a manufacturing process for yet another light-emitting substrate, in accordance with some embodiments of the present disclosure;

FIG. 10c is a diagram illustrating a manufacturing process for yet another light-emitting substrate, in accordance with some embodiments of the present disclosure;

FIG. 11 is a diagram showing simulation results of luminance, under different first gaps and different thicknesses of a first reflective portion, of the light-emitting substrate, in accordance with some embodiments of the present disclosure;

FIG. 12 is a diagram showing simulation results of luminance, under different first gaps, of the light-emitting substrate, in accordance with some embodiments of the present disclosure;

FIG. 13a is a structural diagram of a substrate and a reflective layer of a light-emitting substrate, in accordance with some embodiments of the present disclosure;

FIG. 13b is a structural diagram of a substrate and a reflective layer of another light-emitting substrate, in accordance with some embodiments of the present disclosure;

FIG. 13c is a structural diagram of a substrate and a reflective layer of yet another light-emitting substrate, in accordance with some embodiments of the present disclosure;

FIG. 13d is a physical image showing a surface grain of a reflective layer, in accordance with some embodiments of the present disclosure;

FIG. 13e is a physical image showing a surface grain of another reflective layer, in accordance with some embodiments of the present disclosure;

FIG. 13f is a physical image showing a surface grain of yet another reflective layer, in accordance with some embodiments of the present disclosure;

FIG. 14a is a diagram showing another relative positional relationship of different printing regions and light-emitting devices on a substrate, in accordance with some embodiments of the present disclosure;

FIG. 14b is a diagram showing steps of a manufacturing method for yet another light-emitting substrate, in accordance with some embodiments of the present disclosure;

FIGS. 14c and 14d are diagrams each illustrating a manufacturing process for yet another light-emitting substrate, in accordance with some embodiments of the present disclosure;

FIG. 15a is a diagram showing a relative relationship between a sacrificial layer and light-emitting devices, in accordance with some embodiments of the present disclosure;

FIG. 15b is a sectional view of a light-emitting substrate along the line F-F′ line in FIG. 15a;

FIG. 15c is a diagram showing steps of a manufacturing method for yet another light-emitting substrate, in accordance with some embodiments of the present disclosure;

FIG. 15d is a diagram illustrating a manufacturing process for yet another light-emitting substrate, in accordance with some embodiments of the present disclosure;

FIG. 15e is a sectional view of a light-emitting substrate along the line G-G′ line in FIG. 15d;

FIG. 15f is a diagram illustrating a manufacturing process for yet another light-emitting substrate, in accordance with some embodiments of the present disclosure;

FIG. 15g is a sectional view of a light-emitting substrate along the line H-H′ line in FIG. 15f;

FIG. 16a is a diagram showing a relative relationship between a protective layer and light-emitting devices, in accordance with some embodiments of the present disclosure;

FIG. 16b is a sectional view of a light-emitting substrate along the line J-J′ line in in FIG. 16a;

FIG. 16c is a diagram showing steps of a manufacturing method for yet another light-emitting substrate, in accordance with some embodiments of the present disclosure;

FIGS. 16d to 16e are diagrams illustrating a manufacturing process for yet another light-emitting substrate, in accordance with some embodiments of the present disclosure;

FIG. 17a is a diagram showing an arrangement manner of light-emitting devices, in accordance with some embodiments of the present disclosure;

FIG. 17b is a partial structural diagram of a light-emitting device and a reflective layer in a light-emitting substrate, in accordance with some embodiments of the present disclosure;

FIG. 17c is a partial structural diagram of a light-emitting device and a reflective layer in another light-emitting substrate, in accordance with some embodiments of the present disclosure;

FIG. 17d is a partial structural diagram of a light-emitting device and a reflective layer in yet another light-emitting substrate, in accordance with some embodiments of the present disclosure;

FIG. 18a is a diagram showing yet another relative positional relationship of different printing regions and light-emitting devices on a substrate, in accordance with some embodiments of the present disclosure;

FIG. 18b is a diagram showing steps of a manufacturing method for yet another light-emitting substrate, in accordance with some embodiments of the present disclosure;

FIGS. 18c to 18e are diagrams each illustrating a manufacturing process for yet another light-emitting substrate, in accordance with some embodiments of the present disclosure;

FIG. 18f is a structural diagram of a “coffee ring” around a light-emitting device, in accordance with some embodiments of the present disclosure;

FIG. 18g is a structural diagram of another “coffee ring” around a light-emitting device, in accordance with some embodiments of the present disclosure;

FIG. 19a is a structural diagram showing a relative relationship between driver chips and light-emitting devices, in accordance with some embodiments of the present disclosure;

FIG. 19b is a structural diagram of yet another light-emitting substrate, in accordance with some embodiments of the present disclosure;

FIG. 19c is a structural diagram of yet another light-emitting substrate, in accordance with some embodiments of the present disclosure; and

FIG. 19d is a structural diagram of yet another light-emitting substrate, in accordance with some embodiments of the present disclosure.

### DESCRIPTION OF THE INVENTION

The technical solutions in some embodiments of the present disclosure will be described clearly and completely with reference to the accompanying drawings; obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example”, or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

In the description of some embodiments, the term “connected” and extensions thereof may be used. For example, the term “connected” may be used in the description of some embodiments to indicate that two or more components are in direct physical or electrical contact with each other. The embodiments disclosed herein are not necessarily limited to the content herein.

The phrase “A and/or B” includes the following three combinations: only A, only B, and a combination of A and B.

As used herein, the term “if” is, optionally, construed as “when” or “in a case where” or “in response to determining that” or “in response to detecting” depending on the context. Similarly, depending on the context, the phrase “if it is determined that” or “if [a stated condition or event] is detected” is optionally construed as “in a case where it is determined that” or “in response to determining that” or “in a case where [the stated condition or event] is detected” or “in response to detecting [the stated condition or event]”.

The use of the phrase “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values beyond those stated.

The term such as “about”, “substantially”, and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “perpendicular” includes absolute perpendicularity and approximate perpendicularity, and an acceptable range of deviation of the approximate perpendicularity may also be, for example, a deviation within 5°; the term “equal” includes absolute equality and approximate equality, and an acceptable range of deviation of the approximate equality may be a difference between two equals being less than or equal to 5% of either of the two equals.

It will be understood that, in a case where a layer or an element is referred to as being on another layer or a substrate, it may be that the layer or the element is directly on the another layer or the substrate, or there may be an intervening layer(s) between the layer or the element and the another layer or the substrate.

Exemplary embodiments are described herein with reference to sectional views and/or plan views that are schematic illustrations of idealized embodiments. In the accompanying drawings, thickness of layers and regions may be exaggerated for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

Some embodiments of the present disclosure provide a display apparatus 1. The display apparatus 1 may be any device that displays images whether in motion (e.g., a video) or stationary (e.g., a still image), and regardless of text or image. More specifically, it is expected that the embodiments may be implemented in or associated with a plurality of electronic devices. The plurality of electronic devices may include (but is not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (e.g. odometer displays), navigators, cockpit controllers and/or displays, camera view displays (e.g., rear view camera displays in vehicles), electronic photos, electronic billboards or indicators, projectors, building structures, and packagings and aesthetic structures (e.g., a display for an image of a piece of jewelry).

For example, in a case where the display apparatus 1 is a large-size display apparatus, the display apparatus 1 may include a plurality of sub display apparatuses, and the plurality of sub display apparatuses are tiled together to constitute a large-size display apparatus to meet the large-size display requirement. This display apparatus may be referred to be as a tiled display apparatus.

In some examples, the display apparatus 1 may be a liquid crystal display (LCD) apparatus.

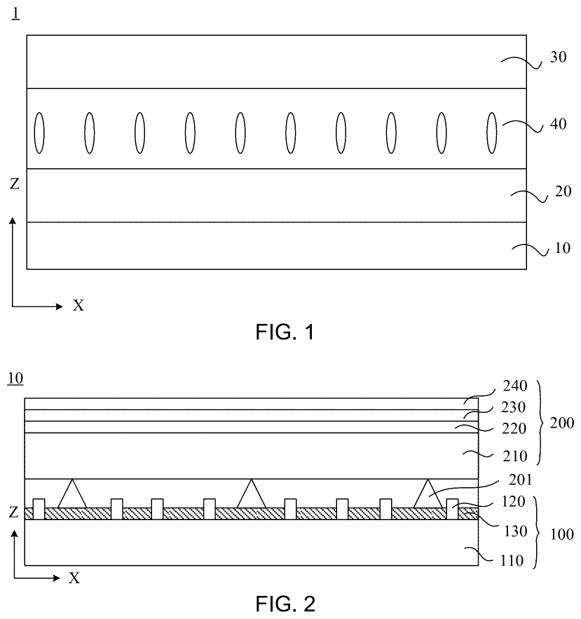

In some examples, as shown in FIG. 1, the display apparatus 1 includes a backlight module 10, an array substrate 20 located on a light exit side of the backlight module 10, and a color filter substrate 30 located on a side of the array substrate 20 away from the backlight module 10.

For example, the backlight module 10 may be used as a light source to provide backlight. For example, the backlight provided by the backlight module 10 may be white light or blue light.

For example, the light exit side of the backlight module 10 refers to a side from which the backlight module 10 emits light.

For example, the array substrate 20 includes a plurality of pixel driving circuits and a plurality of pixel electrodes, and the plurality of pixel driving circuits may be arranged, for example, in an array. The plurality of pixel driving circuits are electrically connected to the plurality of pixel electrodes in a one-to-one correspondence, and the pixel driving circuit provides a pixel voltage for a respective pixel electrode.

For example, the color filter substrate 30 may include a variety of color filters. For example, in a case where the backlight provided by the backlight module 10 is white light, the color filters may include red filters, green filters, and blue-green filters. For example, the red filter may only transmit red light in the incident light, the green filter may only transmit green light in the incident light, and the blue filter can only transmit blue light in the incident light. For another example, in a case where the backlight provided by the backlight module 10 is blue light, the color filters may include red filters and green filters.

For example, the color filter substrate 30 further includes a common electrode. The common electrode may receive a common voltage. Alternatively, the common electrode may be disposed in the array substrate 20, which is not limited in the present disclosure.

In some examples, as shown in FIG. 1, the display apparatus 1 further includes a liquid crystal layer 40 disposed between the color filter substrate 30 and the array substrate 20.

For example, the liquid crystal layer 40 includes a plurality of liquid crystal molecules. For example, an electric field may be created between the pixel electrode and the common electrode, and the liquid crystal molecules located between the pixel electrode and the common electrode may deflect due to the action of the electric field.

It will be understood that the backlight provided by the backlight module 10 may pass through the array substrate 20 and be incident on the liquid crystal molecules of the liquid crystal layer 40. Due to the action of the electric field created between the pixel electrode and the common electrode, the liquid crystal molecules deflect, which changes the amount of light passing through the liquid crystal molecules, so that the light emitted through the liquid crystal molecules reaches a preset luminance. The light is emitted after passing through the filters of different colors in the color filter substrate 30. The emitted light includes light of various colors, such as red light, green light, and blue light, the light of various colors cooperate with each other to enable the display apparatus 1 to achieve the display.

For example, there are many types of backlight modules 10 in the display apparatus 1, which may be set according to actual conditions and will not be limited in the present disclosure.

For example, the backlight module 10 may be an edge-type backlight module, or the backlight module 10 may be a direct-type backlight module.

For convenience of description, the following embodiments of the present disclosure will be introduced by taking an example in which the backlight module 10 is a direct-type backlight module.

In some embodiments, as shown in FIG. 2, the backlight module 10 includes a light-substrate 100 and an optical film 200 disposed on a light exit side of the light-substrate 100.

For example, the optical film 200 includes a diffuser plate 210, a quantum dot film 220, a diffuser sheet 230 and a composite film 240 that are stacked on the light exit side of the light-emitting substrate 100.

For example, the diffusion plate 210 and the diffusion sheet 230 are used to eliminate lamp shadows and uniformize the light emitted by the light-emitting substrate 100 to improve the uniformity of the light.

For example, the quantum dot film 220 is used to convert light emitted by the light-emitting substrate 100. Optionally, in a case where the light emitted by the light-emitting substrate 100 is blue light, the quantum dot film 220 may convert the blue light into white light and improve the purity of the white light.

For example, the composite film 240 is used to increase luminance of light emitted by the light-emitting substrate 100.

It will be understood that the light emitted by the light-emitting substrate 100 is emitted after being incident on the optical film 200, and the luminance of the emitted light is enhanced, and the emitted light has a high purity and good uniformity.

The backlight module 10 may include a plurality of light-emitting substrates 100 and corresponding optical films. The plurality of light-emitting substrates 100 may be tiled together, and the corresponding optical films may also be tiled together, so that the backlight module 10 has a large size. In this case, the backlight module 10 may be referred to be as a tiled display module, and may be applied to the tiled display apparatus described above.

In some examples, as shown in FIG. 2, the backlight module 10 further includes support columns 201 arranged between the light-emitting substrate 100 (e.g., a reflective layer 130 of the light-emitting substrate 100) and the diffusion plate 210 of the optical film 200. As for the reflective layer 130, the reference will be made to the following description, and will not be repeated here.

For example, the support columns 201 may be fixed on the light-emitting substrate 100 through an adhesive. The support columns 201 may be used to support the optical film 200 and allow the light emitted by the light-emitting substrate 100 to obtain a certain optical distance, thereby further eliminating lamp shadows and improving the uniformity of the light.

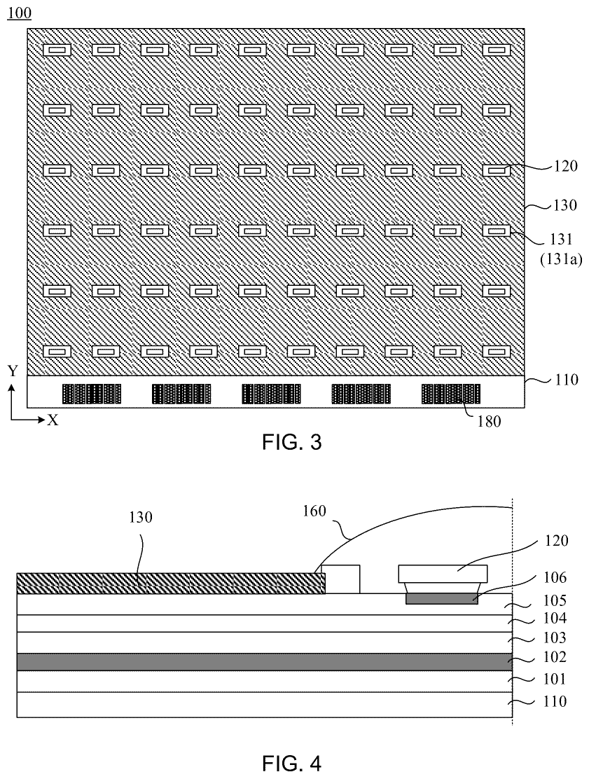

In some embodiments, as shown in FIGS. 2 and 3, the light-emitting substrate 100 includes a substrate 110 and a plurality of light-emitting devices 130 and a reflective layer 130 that are disposed on a side of the third substrate 110.

In some examples, the substrate 110 may be a flexible substrate. The flexible substrate may be, for example, a polyethylene terephthalate (PET) substrate, a polyethylene naphthalate two formic acid glycol ester (PEN) substrate, or a polyimide (PI) substrate.

In some examples, the substrate 110 may be a rigid substrate. For example, the substrate may be made of glass. The substrate 110 may also be a printed circuit board (PCB), an aluminum substrate, or the like.

In some examples, the plurality of light-emitting devices 120 may be LEDs, such as Mini LEDs, or micro LEDs.

For example, as shown in FIG. 3, the plurality of light-emitting devices 120 may be arranged in a plurality of columns in a first direction X and arranged in a plurality of rows in a second direction Y.

For example, an angle between the first direction X and the second direction Y may be 85°, 90°, 95°, or the like. The embodiments of the present disclosure are described by taking an example in which the angle between the first direction X and the second direction Y is 90°.

For example, the light-emitting devices 120 may serve as a light source of the light-emitting substrate 100.

For example, the light-emitting substrate 100 further includes an alignment mark and a panel ID that are disposed on the substrate 110.

For example, the alignment mark is used to realize the installation alignment between the light-emitting substrate 100 and the optical film 200 and the like. The substrate number is used to mark and identify a single light-emitting substrate 100. Therefore, the alignment mark and the panel ID need to be exposed on the reflective layer 130 to facilitate alignment or identification.

In some examples, the reflective layer 130 has a plurality of openings 131.

For example, the plurality of openings 131 of the reflective layer 130 are used to expose devices such as the light-emitting devices 120 (or the alignment marks and panel ID) located on the substrate 110 from the surface of the reflective layer 130, which is prevented the reflective layer 130 from covering the light-emitting devices 120 to prevent the reflective layer 130 from blocking the light emitted by the light-emitting devices 120, thereby preventing from affecting the luminous efficiency of the light-emitting devices 120. As a result, the luminous efficiency of the light-emitting substrate 100 is improved.

For example, the plurality of openings 131 include a plurality of first openings 131a. A light-emitting device 120 is located in a first opening 131a.

For example, the plurality of first openings 131a may be in one-to-one correspondence with the plurality of light-emitting devices 120.

In some examples, the reflective layer 130 has a certain reflectivity and may reflect the light emitted by the plurality of light-emitting devices 120, thereby improving the light utilization efficiency of the light-emitting devices 120. In addition, the reflective layer 130 may also protect the light-emitting substrate 100 to prevent the light-emitting substrate 100 from being corroded by moisture and oxygen and from being scratched.

With the such arrangement, the light emitted by the light-emitting devices 120 may be prevented from being blocked by the edges of the reflective layer 130 as much as possible, thereby improving the luminous efficiency of the light-emitting substrate 100.

In some examples, as shown in FIG. 4, a transition layer 101, a first conductive layer 102, a first passivation layer 103, an adhesive layer 104, a second passivation layer 105, and the second conductive layer 106 are included between the substrate 110 and the reflective layer 130.

For example, a material of the transition layer 101 may be silicon nitride. The transition layer 101 may increase the adhesion between the substrate 110 and the first conductive layer 102.

For example, the first conductive layer 102 and the second conductive layer 106 may be made of the same material, and the material may be a metallic material, such as copper. The conductive layer may include signal lines to provide signals for the light-emitting devices 120.

For example, the first passivation layer 103 and the second passivation layer 105 may be made of the same or different materials. The first passivation layer 103 may provide insulation protection for the first conductive layer 102 to prevent the first conductive layer 102 from electromagnetic interference. The second passivation layer 105 may provide insulation protection for the second conductive layer 106 to prevent the second conductive layer 106 from electromagnetic interference.

For example, the adhesive layer may be made of a transparent resin or the like. The adhesive layer is used to enhance the fixation between the first passivation layer and the second passivation layer.

In an implementation, the reflective layer is generally formed by applying a reflective material to the substrate and then curing the reflective material. The reflective material is composed of a solute with a high reflectivity and a solvent. During the curing process of the reflective material, the precipitates of the reflective material will adhere to the pad connected to the light-emitting device on the light-emitting substrate to form a solder mask on the surface of the pad, which will reduce the solder ability of the pad, and reduce the welding reliability of light-emitting device. In some manufacturing methods for the light-emitting substrate, before the die bonding process, an electroless nickel immersion gold process is provided, and a nickel-gold layer is plated on the pad to improve the welding performance and anti-corrosion performance of the pad. After the electroless nickel immersion gold process is performed, the reflective layer is manufactured. During the curing process of the reflective material, the precipitates of the reflective material will adhere to the surface of the nickel-gold layer of the pad to form the solder mask, which will affect the soldering performance of the pad. Even if the electroless nickel immersion gold process is performed after the reflective layer is formed, the yield of the electroless nickel immersion gold process will be greatly reduced due to the fact that the precipitates of the reflective material cannot be removed from the surface of the pad. In addition, according to various size specifications of the light-emitting substrate, different manufacturing methods may be used to form the light-emitting substrate. For example, for a large-size light-emitting substrate, the manufacturing method generally includes the following steps: material preparation→forming the reflective layer by a screen printing process→automated optical inspection (AOI)→die bonding→dot repair→AOI→encapsulation. In the manufacturing method, the shape accuracy of the reflective layer is small, and the gap between the light-emitting device and the reflective layer can only reach the level of 0.3 mm±0.15 mm; moreover, the gap may leak light, and it is difficult to reflect all the light emitted by the light-emitting device, resulting in light and dark optical fringes and regional display mura phenomenon appearing on the light-emitting substrate and the display module. For another example, for a medium-large-sized light-emitting substrate (a glass substrate) or small-medium-sized light-emitting substrate (a PCB substrate), the manufacturing method generally includes the following steps: material preparation→forming the reflective layer by a screen printing process→exposure→development→AOI→die bonding→encapsulation. In this manufacturing method, the accuracy of the reflective layer is improved, and the gap between the light-emitting device and the reflective layer can reach the level of 0.05 mm±0.015 mm. However, it is necessary to consider the accuracy of die bonding after the reflective layer is formed, and it is necessary to prevent the gap between the light-emitting device and the reflective layer from being set to only 0.1 mm caused by the problem of errors in the fixed position of the light-emitting device, which is caused by a case that the plurality of the light-emitting devices may be fixed at the same time due to a fact that the previously formed reflective layer easily adheres to the light-emitting devices during the process of fixing a single light-emitting device in the die bonding process. The die bonding process includes the reflow soldering process. Due to the high temperature of the reflow soldering process, the reflow soldering process will cause the material of the previously formed reflective layer to oxidize and turn yellow, resulting in a decrease in the reflectivity of the reflective layer (the reflectivity is attenuated by 1% to 2%) and a decrease in the luminance of the light-emitting substrate by 3% to 5%, which will cause the brightness of the light-emitting module and display apparatus is reduced.

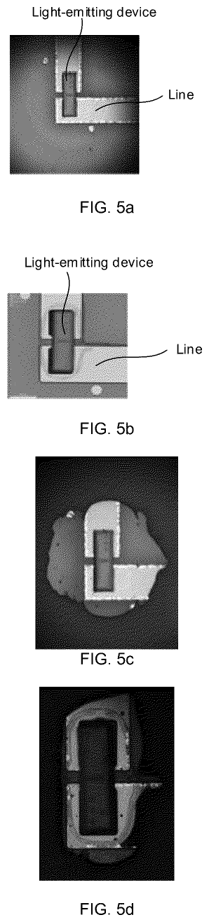

In another implementation, the reflective layer is formed after the die bonding process, that is, the die bonding process is first performed to weld the light-emitting devices to the light-emitting substrate, and then the reflective layer is formed. However, after the die bonding process, there is a welding residue on the substrate, such as flux used in the welding process, and the welding residue will repel the reflective material in the subsequent manufacturing process for the reflective layer (for example, FIG. 5a shows the morphology of the welding residue diffusing all around, FIG. 5b shows the morphology of the welding residue diffusing along a line, FIG. 5c shows the repelling morphology of the formed reflective layer diffusing all around, and FIG. 5d shows the repelling morphology of the formed reflective layer diffusing along a line), resulting in a great gap between the light-emitting device and the reflective layer, which will affect the shape accuracy of the reflective layer, and reduce the brightness of the backlight module and display apparatus.

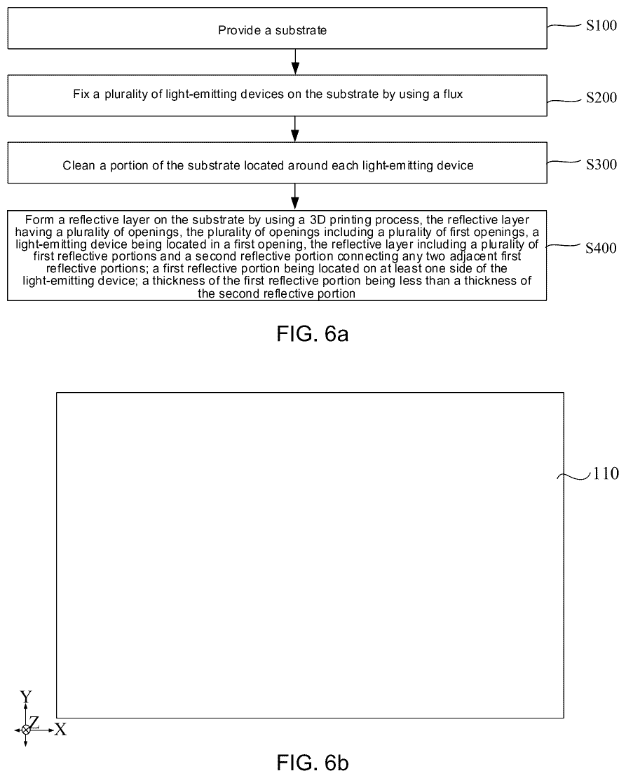

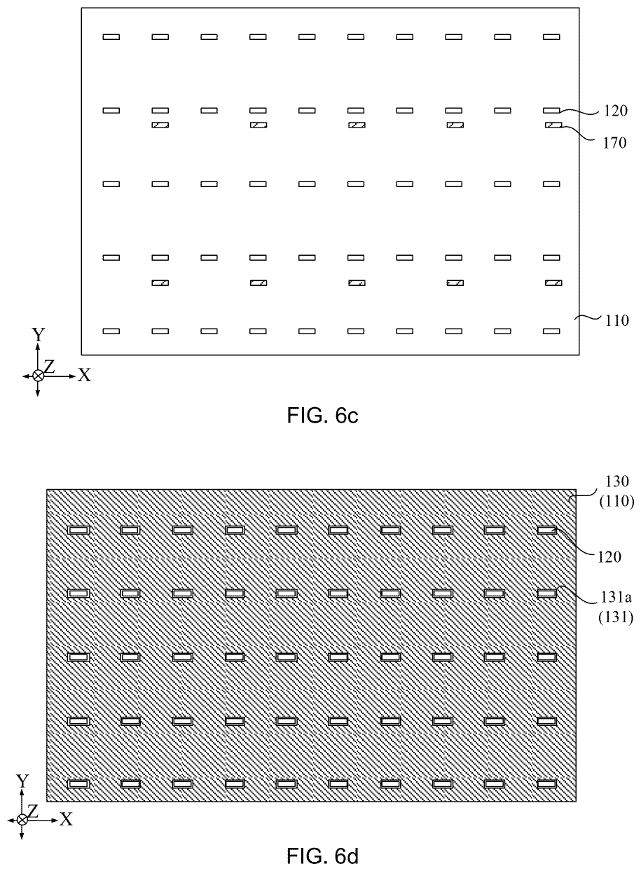

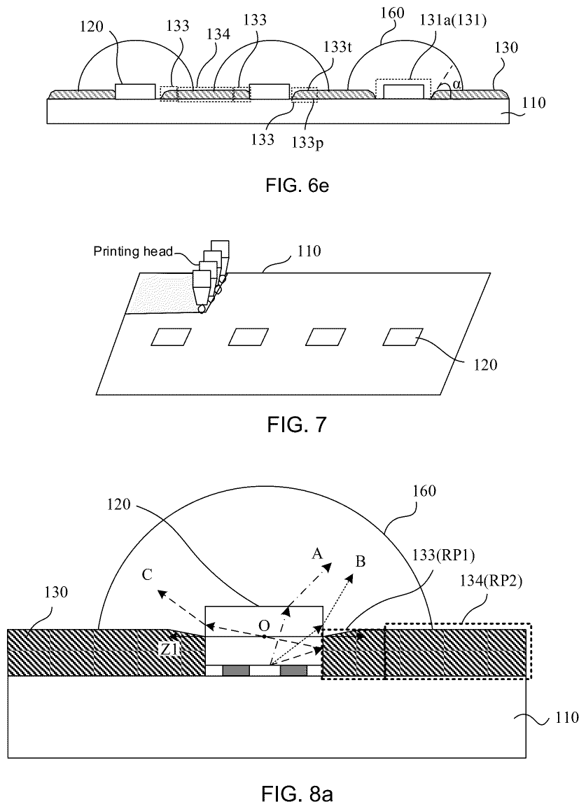

Based on this, some embodiments of the present disclosure provide a manufacturing method for a light-emitting substrate 100. As shown in FIG. 6a, the manufacturing method includes S100 to S400.

In S100, as shown in FIG. 6b, a substrate 110 is provided.

In some examples, the substrate 110 may be a PET substrate, a PI substrate, a PEN substrate, a glass substrate, a PCB substrate, an aluminum substrate, or the like.

In S200, as shown in FIG. 6c, a plurality of light-emitting devices 120 are fixed on the substrate 110 by using a flux.

For example, the flux may include rosin and resin.

For example, corresponding pads are provided on the substrate 110 at positions where the light-emitting devices 120 are to be fixed. The process of fixing the light-emitting device 120 may include, for example, dipping or printing solder and flux onto the pad, then placing the corresponding light-emitting device 120 on the pad, and then fixing the light-emitting device 120 to the pad on the substrate 110 by using a reflow soldering process.

For example, the light-emitting device 120 may be a LED, such as a micro LED or a mini LED.

Considering an example in which the light-emitting device 120 is a mini LED, the structure of the mini LED may be a wire-bonding structure, a vertical structure or a flip structure.

For example, the plurality of light-emitting devices 120 may be evenly distributed on the substrate 110, so that the entire surface of the light-emitting substrate 100 emits light more uniformly, thereby improving the display quality of the backlight module 10 and the display apparatus 1.

In S300, a portion of the substrate 110 located around each light-emitting device 120 is cleaned.

For example, the cleaning operation may include wet cleaning and dry cleaning.

For example, wet cleaning means that using water-based rosin cleaner, ethanol or ethyl acetate to clean the surrounding of the light-emitting device 120, so as to remove the flux residue. Thus, in the subsequent printing of the reflective material, it is possible to alleviate and eliminate the repelling phenomenon to improve the shape accuracy of the formed reflective layer 130, thereby increasing the luminance of the light-emitting substrate 100.

For another example, dry cleaning means that using plasma surface treatment to change the surface tension coefficient of the portion of the substrate 110 around the light-emitting device 120, so that the surface tension coefficient is increased from less than 30 to a range approximately 40 to approximately 60, thereby improving the wetting effect of the reflective material on the substrate 110. Thus, in the subsequent printing of the reflective material, it is possible to alleviate and eliminate the repelling phenomenon to improve the shape accuracy of the formed reflective layer 130, thereby increasing the luminance of the light-emitting substrate 100.

In S400, as shown in FIG. 6d, the reflective layer 130 is formed on the substrate 110 by using a 3D printing process. The reflective layer 130 has a plurality of openings 131. The plurality of openings 131 include a plurality of first openings 131a. A light-emitting device 120 is located in a first opening 131a. As shown in FIG. 6e, the reflective layer 130 includes a plurality of first reflective portions 133 and a second reflective portion 134 connecting any two adjacent first reflective portions 133. The first reflective portion 133 is located on at least one side of the light-emitting device 120. A thickness of the first reflective portion 133 is less than a thickness of the second reflective portion 134.

In some examples, the material of the reflective layer 130 may include epoxy resin, phenyl silicone resin, or polytetrafluoroethylene resin.

For example, in the embodiments of the present disclosure, a 3D printing device may be used to perform the 3D printing process. As shown in FIG. 7, the 3D printing device includes multiple printing heads with the same function, and the printing heads are each provided with a printing nozzle. The material of the reflective layer 130 is put into the 3D printing device after certain pretreatment, and then, by controlling the state of the printing nozzle, the printing nozzle is moved on the substrate 110 according to the set printing path, so that the material of the reflective layer 130 is ejected from the printing nozzle in dots. The dots of the reflective layer material are dropped onto the substrate 110 and converge together to form a printing strip extending along the printing path. All printing strips collectively form the reflective layer 130. In the regions of the substrate 110 corresponding to the plurality of openings 131 of the reflective layer 130, the printing nozzle is closed, thereby forming the plurality of openings 131.

For example, the 3D printing has a high degree of freedom, the printing head ejects the fluid in non-contact manner onto the substrate 110 to be printed, and the dimensional accuracy of the reflective layer 130 and the dimensional accuracy of the opening 131 that are formed by printing are relatively high. In this way, it is beneficial to increase the proportion of the area of the substrate 110 occupied by the reflective layer 130, thereby increasing the reflectivity of the reflective layer 130 and improving the utilization rate of light emitted by the light-emitting device 120.

For example, the first reflective portion 133 is closer to the light-emitting device 120 than the second reflective portion 134.

In some examples, for the case where the first reflective portion 133 is located on at least one side of the light-emitting device 120, various arrangement manners may be provided. For example, the first reflective portion 133 may be located on a side of the light-emitting device 120. For another example, the first reflective portion 133 may be located on adjacent two sides or two opposite sides of the light-emitting device 120. For yet another example, the first reflective portion 133 may be located on three sides of the light-emitting device 120. For yet another example, the first reflective portion 133 may surround the corresponding light-emitting device 120.

For example, an orthographic projection of the light-emitting device 120 on the substrate 110 may be in various shapes, such as a circle or a rectangle.

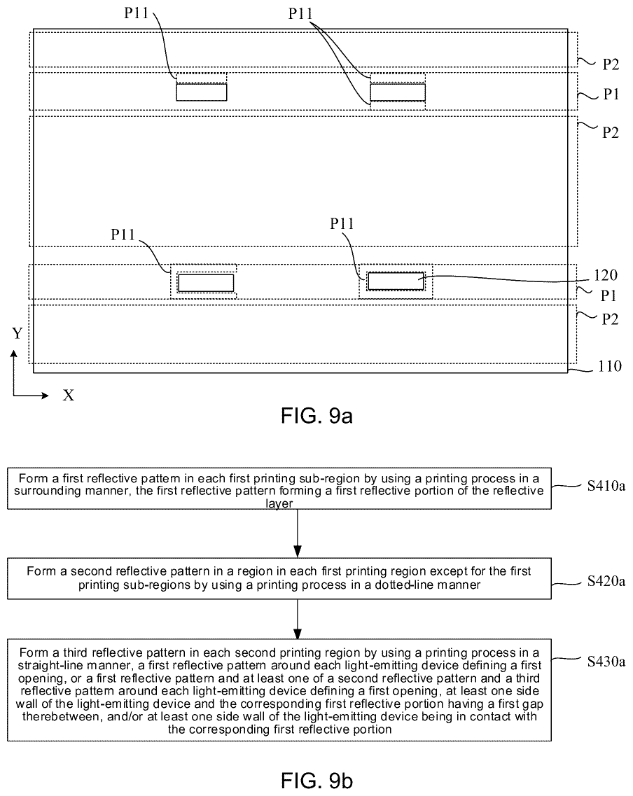

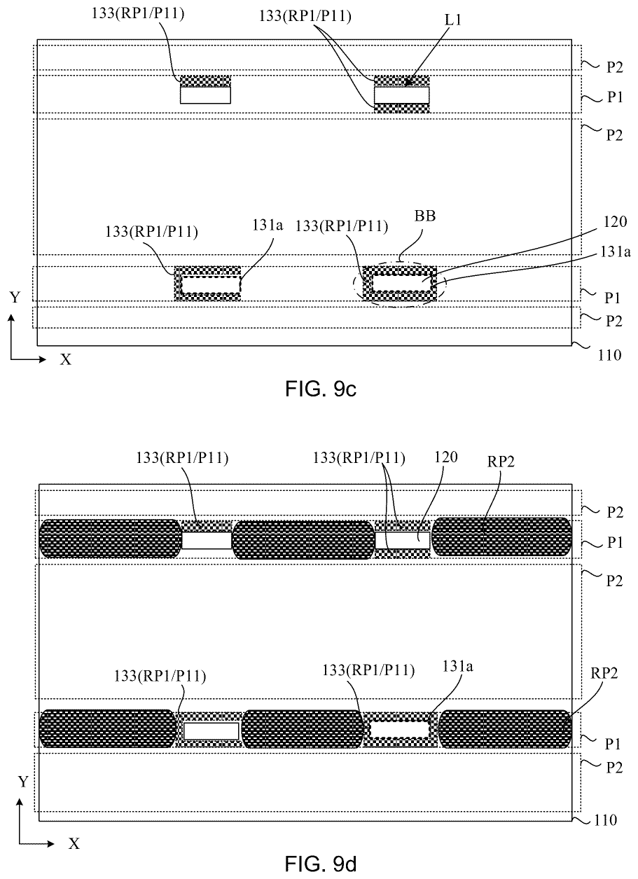

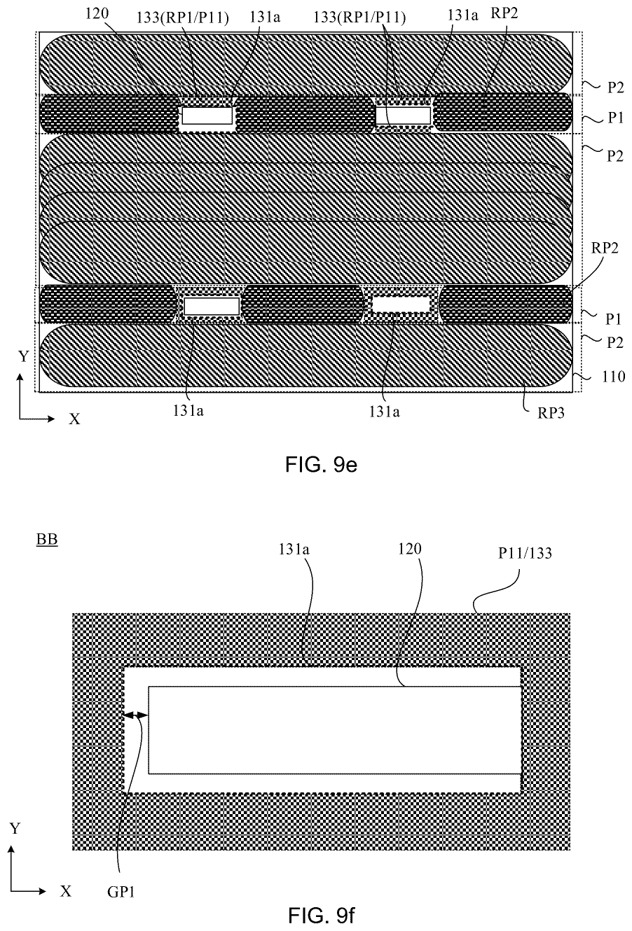

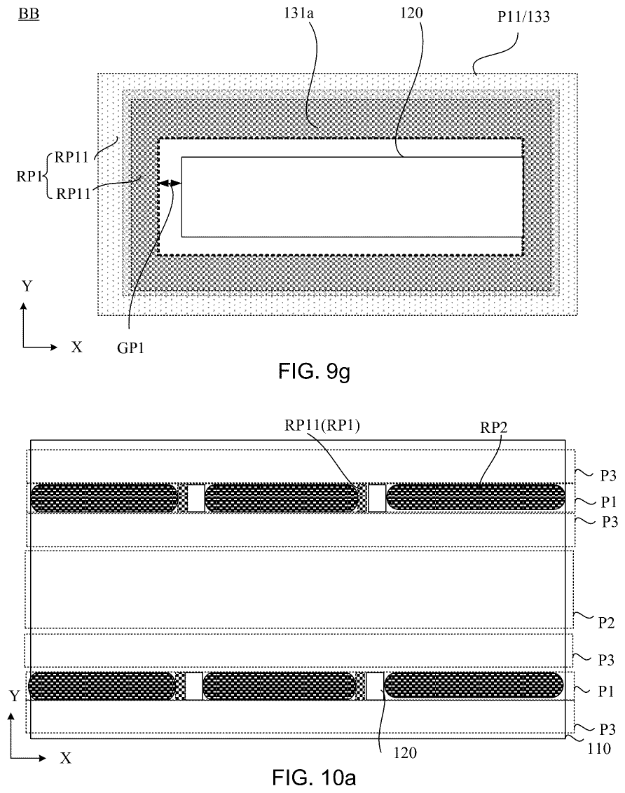

For the rectangular light-emitting device 120, compared with the shape accuracy of the portion of the first reflective portion 133 corresponding to the short side, the shape accuracy of the portion of the first reflective portion 133 corresponding to the long side has a greater impact on the luminous efficiency of the light-emitting substrate 100. Therefore, as shown in FIG. 9c, in a case where the first reflective portion 133 is located on two opposite sides of the light-emitting device 120 and the orthographic projection of the light-emitting device 120 on the substrate 110 is in a shape of a rectangle, the first reflective portion 133 is located on sides of two long sides L1 of the rectangle. Thus, the luminous efficiency of the light-emitting substrate 100 may be improved, the printing cost of the reflective layer 130 may be reduced, and the printing efficiency of the reflective layer 130 may be improved.

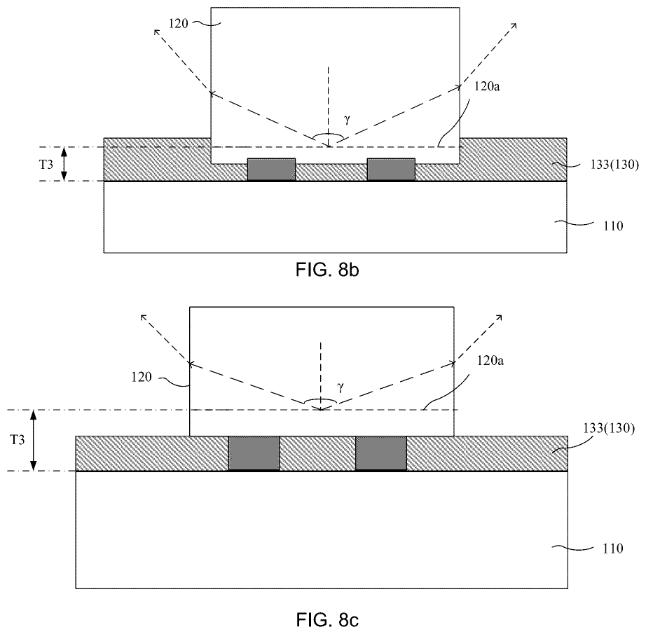

It will be understood that, as shown in FIG. 8a, the luminous efficiency of the light-emitting substrate is related to the light exit mode of the light-emitting device. There are three paths for the light emitted by the light-emitting device 120 to emit, which are a path A, a path B and a path C. The light emitted by the light-emitting device 120 is emitted through the path A and the path B, i.e., the light is emitted directly from the top wall or side wall of the light-emitting device 120 without passing through the reflective layer 130, resulting in a less loss of light. The light emitted by the light-emitting device 120 is emitted through the path C, i.e., the light is reflected by the first reflective portion 133 and then emitted from the side wall of the light-emitting device 120, resulting in a great loss of light. The greater the proportion of light emitted from the path C, the greater the loss of light of the light-emitting device, and the less the light extraction efficiency of the light-emitting substrate. In the embodiments of the present disclosure, the thickness of the first reflective portion 133 is set to be less than the thickness of the second reflective portion 134, which may ameliorate the situation where light is reflected on the side walls of the first reflective portion 133 and then emitted, so that the light emitted through the path C accounts for a small proportion of the light emitted by the light-emitting device 120. As a result, the loss of light of the light-emitting device 120 is small, which may improve the light extraction efficiency of the light-emitting substrate 100, thereby improving the display brightness of the backlight module 10 and the display apparatus 1, and reducing the power consumption of the backlight module 10 and the display apparatus 1.

In some of the embodiments of the present disclosure, the light-emitting substrate 100 is manufactured by using the above method. The light-emitting devices 120 are first fixed on the substrate 110, and then the reflective layer 130 (the first openings 131a corresponding to the light-emitting devices 120 are provided in the reflective layer 130) is formed by using a 3D printing process, so that the reflective layer 130 is formed after the die bonding process (here refers to the process of fixing the light-emitting devices 120 on the substrate 110). Thus, it is possible to prevent the precipitates of the reflective material from adhering to the pad, which may avoid the formation of the solder mask on the surface of the pad to prevent from affecting the welding performance of the pad, thereby improving the yield of the light-emitting substrate 100. The light-emitting substrate 100 is manufactured by using the above method, it is possible to avoid the risk of reduction in the reflectivity of the reflective layer 130 due to the reflow soldering process in the die bonding process, which may improve the luminous efficiency of the light-emitting substrate 100, thereby improving the display brightness of the backlight module 10 and display apparatus 1, and reducing the power consumption of the backlight module 10 and the display apparatus 1. Moreover, in the manufacturing method provided by the embodiments of the present disclosure, the dot repair process is eliminated, which reduces the number of high-temperature curing processes required for the light-emitting substrate 100, thereby simplifying the manufacturing process of the light-emitting substrate 100.

In addition, in the implementation, after the light-emitting device is fixed, a large amount of residual flux will accumulate around the light-emitting device, and the surface tension coefficient of the flux is greatly different from the surface tension coefficient of the reflective material, which causes the repelling phenomenon occurring between the reflective material and the flux during the process of printing the reflective material, thereby reducing the shape accuracy of the reflective layer. However, in the embodiments of the present disclosure, the light-emitting substrate 100 is manufactured by using the above method, before forming the reflective layer 130 by using the 3D printing process, the surroundings of the light-emitting device 120 are cleaned to remove residual flux, or the surface tension coefficient of the portion of the substrate 110 located around the light-emitting device 120 is improved, which may alleviate the repelling phenomenon between the flux and the reflective material, thereby reducing the gap between the light-emitting device 120 and the reflective layer 130. As a result, it is possible to improve the shape accuracy of the reflective layer 130, and alleviate the problem of light and dark optical fringes and regional display mura phenomenon of the light-emitting substrate and the display module, thereby improving the brightness and display effect of the light-emitting substrate 100 and the backlight module 10. In the embodiments of the present disclosure, the thickness of the first reflective portion 133 is less than the thickness of the second reflective portion 134, which may reduce the situation where light is emitted after being reflected on the side wall of the first reflective portion 133, so that the light emitted through the path C accounts for a small proportion of the light emitted by the light-emitting device 120. As a result, the loss of light of the light-emitting device 120 is small, which may improve the light extraction efficiency of the light-emitting substrate 100, thereby improving the display brightness of the backlight module 10 and the display apparatus 1 and reducing the power consumption of the backlight module 10 and the display apparatus 1.

In some embodiments, as shown in FIG. 9a, the substrate 110 has a plurality of first printing regions P1 and a plurality of second printing regions P2. At least one second printing region P2 is disposed between two adjacent first printing regions P1, and a row of light-emitting devices 120 is located in a first printing region P1.

Exemplarily, a row of light-emitting devices 120 corresponds to a first printing region P1. Here, the first printing region P1 extends in the first direction X, and the second printing region P2 located between two adjacent first printing regions P1 extends in the first direction X.

For example, a second printing region P2 is disposed between two adjacent first printing regions P1; here, the second printing region P2 extends in the first direction X.

For another example, multiple second printing regions P2 are disposed between two adjacent first printing regions P1.

Of course, it is possible to set that a column of light-emitting devices 120 corresponds to a first printing region P1. Here, the first printing region P1 extends in the second direction Y, and the second printing region P2 located between two adjacent first printing regions P1 extends in the second direction Y.

In some examples, as shown in FIG. 9a, the first printing region P1 includes a plurality of first printing sub-regions P11 arranged sequentially at intervals in the first direction X; a first printing sub-region P11 is located on at least one side of a light-emitting device 120.

For example, a first printing sub-region P11 corresponds to a light-emitting device 120, and the plurality of first printing sub-regions P11 are in one-to-one correspondence with the light-emitting devices 120 in a row.

For example, a first printing sub-region P11 is located on a side of a light-emitting device 120.

For another example, a first printing sub-region P11 is located on two adjacent sides or two opposite sides of a light-emitting device 120.

For yet another example, a first printing sub-region P11 is located on three sides of a light-emitting device 120.

For yet another example, a first printing sub-region P11 surrounds a light-emitting device 120.

In some embodiments, as shown in FIG. 9b, the reflective layer 130 is formed on the substrate 110 by using a 3D printing process includes S410a to S430a.

In S410a, as shown in FIG. 9c, a first reflective pattern RP1 is formed in each first printing sub-region P11 by using a printing process in a surrounding manner, and the first reflective pattern RP1 forms the first reflective portion 133 of the reflective layer 130.

For example, the printing process in a surrounding manner means that the overall printing path of the 3D printing device is non-linear, and after printing is completed, the overall outline of the formed printed pattern is in a shape of a closed annulus or a part of an annulus. For the printing process in a surrounding manner, the fluid output from the printing head is less, which is conducive to high-precision control for the fluid output. In this way, the thickness of the printed pattern formed by printing is small, and the shape accuracy of the printed pattern may be improved.

By using the printing process in a surrounding manner to form the first reflective portion 133, the distance between the first reflective portion 133 and the light-emitting device 120 may be precisely controlled, which achieves zero distance between the light-emitting device 120 and the first reflective portion 133, thereby improving the reflectivity of the reflective layer 130, and improving the brightness of the light-emitting substrate 100.

For example, in a case where a first printing sub-region P11 surrounds a light-emitting device 120, the overall outline of the first reflective pattern RP1 is in a shape of a closed annulus, and the first reflective pattern RP1 defines the first opening 131a.

For another example, in a case where a first printing sub-region P11 is located on a side of a light-emitting device 120, the overall outline of the first reflective pattern RP1 is in a shape of a part of an annular. In this case, the first reflective pattern RP1 forms part of the side walls of the first opening 131a.

It will be noted that the printing process in a surrounding manner has a certain scope of application. The light-emitting device 120 has a certain thickness, and a pad is provided between the light-emitting device 120 and the substrate 110. As shown in FIG. 8b, there is a certain distance T3 between a light-emitting surface 120a of the light-emitting device 120 and the substrate 110. The distance T3 is, for example, is 15 μm, and a light-emitting angle γ of the light-emitting device 120 is 140°. In this case, the minimum thickness of the first reflective portion 133 of the reflective layer 130 is greater than the distance T3, and the printing process in a surrounding manner may be used to form the first reflective portion 133. In a case where the distance T3 is greater than the thickness (60 μm) of the reflective layer, i.e., the distance between the light-emitting surface 120a and the substrate 110 is greater than the thickness of the reflective layer 130, as shown in FIG. 8c, the thickness of the first reflective portion 133 may be the same as the thickness of the second reflective portion 134, and there is no need to use the printing process in a surrounding manner to form the first reflective portion 133.

In S420a, as shown in FIG. 9d, a second reflective pattern RP2 is formed in a region in each first printing region P1 except for the first printing sub-regions P11 by using a printing process in a dotted-line manner.

For example, the printing process in a dotted-line manner means that the 3D printing device moves along a set printing path, and by controlling the printing nozzle to be turned on or off intermittently, after a single printing is completed, a printed pattern that is formed is a discontinuous and intermittent printing strip whose shape similar to a dotted line.

For example, the region in each first printing region P1 except for the first printing sub-regions P11 refers to a region between two adjacent light-emitting devices 120, except for the first printing sub-regions P11, in the first printing region P1 where a row of light-emitting devices 120 is located in a case where a first printing region P1 corresponds to a row of light-emitting devices 120, or a region between two adjacent light-emitting devices 120, except for the first printing sub-regions P11, in the first printing region P1 where a column of light-emitting devices 120 is located in a case where a first printing region P1 corresponds to a column of light-emitting devices 120.

Therefore, among the plurality of second reflective patterns RP2, any two adjacent second reflective patterns RP2 are separated by a light-emitting device 120.

With such the above method, the first reflective pattern RP1 formed by the printing process in a surrounding manner defines or forms part or all of side walls of the first opening 131a. Therefore, it is possible to reduce the number of side walls of the first opening 131a formed by the second reflective pattern RP2 that is formed by the printing process in a dotted-line manner, and reduce the limit effect of the printing process in a dotted-line manner, thereby improving the dimensional accuracy of the first opening 131a.

In S430a, as shown in FIG. 9e, a third reflective pattern RP3 is formed in each second printing region P2 by using a printing process in a straight-line manner. The first reflective pattern around each light-emitting device defining the first opening; alternatively, the first reflective pattern RP1 and at least one of the second reflective pattern RP2 and the third reflective pattern RP3 around each light-emitting device 120 define the first opening 131a; at least one side wall of the light-emitting device 120 and the corresponding first reflective portion 133 have a first gap GP1 therebetween (as shown in FIG. 9f), and/or at least one side wall of the light-emitting device 120 is in contact with the corresponding first reflective portion 133.

For example, the printing process in a straight-line manner means that the 3D printing device moves along a set printing path, and after a single printing is completed, a printed pattern that is formed is a continuous and unintermittent printing strip whose shape similar to a straight line.

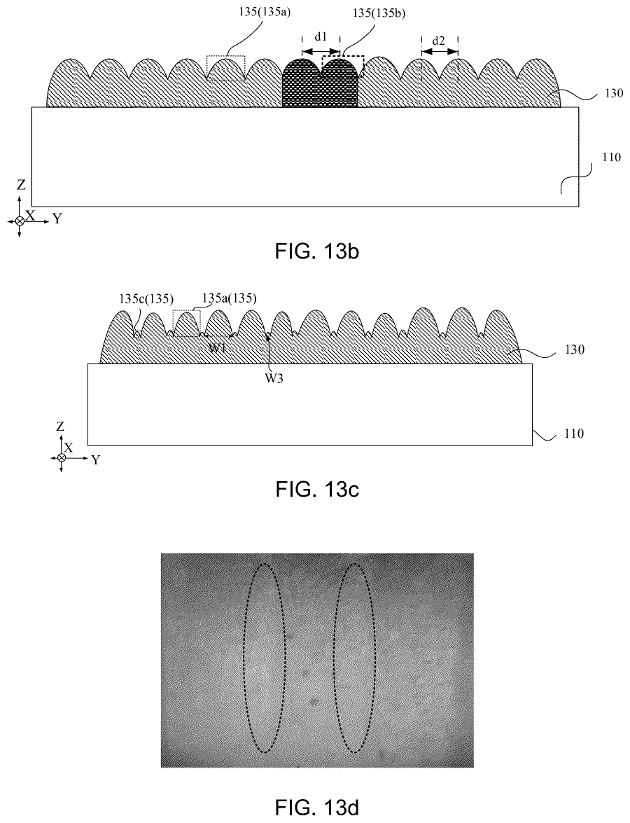

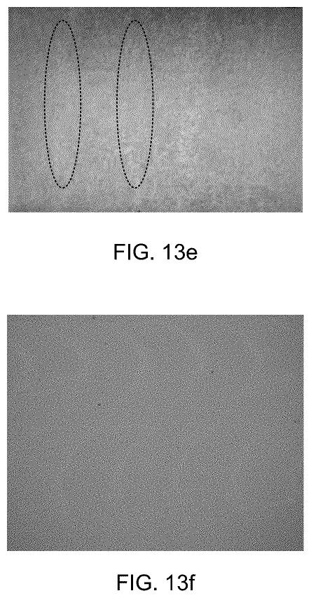

It will be noted that, as shown in FIG. 13b, a printing step size d1 of the printing process in a dotted-line manner is less than or equal to a printing step size d2 of the printing process in a straight-line manner. Here, the printing step size is a distance between center lines of two adjacent printing strips, which is actually a distance that the 3D printing device moves in a direction perpendicular to the printing path after printing a single printing strip, i.e., a dimension of a protruding structure 135 along an arrangement direction of the protruding structures 135 described below. For example, the printing step size of the printing process in a straight-line manner is in a range of 0.1 mm to 3.0 mm, inclusive; and the printing step size of the printing process in a dotted-line manner is in a range of 0.1 mm to 1.5 mm, inclusive. Therefore, the printing accuracy of the printing process in a dotted-line manner is greater than the printing accuracy of the printing process in a straight line manner. The printing step size and fluid output of the printing process in a surrounding manner are less than those of the dotted line printing process, respectively. Therefore, the printing accuracy of the printing process in a surrounding manner is greater than the printing accuracy of the printing process in a dotted-line manner.

For example, the first opening 131a has various shapes in a top view, such as a rectangle, or a circle. Considering an example in which the first opening 131a is in a shape of a rectangle in a top view, the first opening 131a includes four side walls, at least one of which is formed by the first reflective pattern RP1.

There are various positional relationships between the side walls of the light-emitting device 120 and the corresponding first reflective portion 133, which may be set according to actual needs, and the present disclosure does not limit thereto.

In a case where the light-emitting device 120 has a plurality of side walls, the relative positional relationship between each of the plurality of side walls of the light-emitting device 120 and the corresponding first reflective portion 133 may be the same or different.

In some examples, as shown in FIG. 9f, at least one side wall of the light-emitting device 120 and the corresponding first reflective portion 133 have a first gap GP1 therebetween.

For example, there is a first gap GP1 between one side wall or each of multiple side walls of the light-emitting device 120 and the corresponding first reflective portion 133. FIG. 9f shows that there is a first gap GP1 between each of three side walls of the light-emitting device 120 and the corresponding first reflective portion 133.

Considering an example in which the light-emitting device 120 is in a shape of a rectangular in the top view, there may be a first gap GP1 between one side wall of the light-emitting device 120 and the first reflective portion 133, or there may be a first gap GP1 between each of the four side walls of the light-emitting device 120 and the first reflective portion 133. The distance, i.e., a width of the first gap GP1, between each of the four side walls and the first reflective portion 133 may be the same or different.

For example, the width of the first gap GP1 is less than or equal to 150 μm.

For example, the width of the first gap GP1 refers to a dimension of the first gap GP1 in a direction perpendicular to the side wall of the corresponding light-emitting device 120.

For example, the width of the first gap GP1 may be 150 μm, 100 μm, 50 μm, 25 μm or 10 μm.

In the embodiments of the present disclosure, the light-emitting substrate 100 is manufactured by the above manufacturing method, which may make the width of the first gap GP1 between the side wall of the light-emitting device 120 and the corresponding first reflective portion 133 in the light-emitting substrate 100 small, thereby improving the area proportion of the reflective layer 130 in the light-emitting substrate 100. As a result, it is possible to improve the luminous efficiency of the light-emitting substrate 100, alleviate the problem of light and dark optical fringes and mura phenomenon of the light-emitting substrate 100, and enhance the luminance of the light-emitting device 120, thereby improving the brightness of the backlight module 10 and the display apparatus 1, and reducing the power consumption of the backlight module 10 and the display apparatus 1.

In some other examples, as shown in FIG. 9f, at least one side wall of the light-emitting device 120 is in contact with the corresponding first reflective portion 133.

For example, one side wall or each of multiple side walls of the light-emitting device 120 is in contact with the corresponding first reflective portion 133.

Considering an example in which of the light-emitting device 120 is in a rectangle in the top view, one side wall of the light-emitting device 120 may be in contact with the first reflective portion 133 (there may be a first gap GP1 between each of the remaining three side walls and the first reflective portion 133); alternatively, all four side walls of the light-emitting device 120 are each in contact with the first reflective portion 133.

In the embodiments of the present disclosure, the light-emitting substrate 100 is manufactured by using the above manufacturing method, which may make the side wall(s) of the light-emitting device 120 in the light-emitting substrate 100 each in contact with the corresponding first reflective portion 133, thereby improving the area proportion of the reflective layer 130 in the light-emitting substrate 100. As a result, it is possible to improve the luminous efficiency of the light-emitting substrate 100, alleviate the problem of light and dark optical fringes and mura phenomenon of the light-emitting substrate 100, thereby improving the luminance of the backlight module 10 and the display apparatus 1, and reducing the power consumption of the backlight module 10 and the display apparatus 1.

In some other examples, as shown in FIG. 9f, there is a first gap GP1 between at least one side wall of the light-emitting device 120 and the corresponding first reflective portion 133, and at least one side wall of the light-emitting device 120 is in contact with the corresponding first reflective portion 133.

For example, one side wall of the light-emitting device 120 is in contact with the corresponding first reflective portion 133, and there is a first gap GP1 between each of the remaining side walls of the light-emitting device 120 and the corresponding first reflective portion 133.

For another example, there is a first gap GP1 between one side wall of the light-emitting device 120 and the corresponding first reflective portion 133, and the remaining side walls of the light-emitting device 120 are each in contact with the corresponding first reflective portion 133.

For another example, as shown in FIG. 9f, there is a first gap GP1 between each of the three side walls of the light-emitting device 120 and the corresponding first reflective portion 133, and the remaining side wall of the light-emitting device 120 is in contact with the corresponding first reflective portion 133.

In the embodiments of the present disclosure, the light-emitting substrate 100 is manufactured by using the above manufacturing method, which may make the side wall(s) of the light-emitting device 120 in the light-emitting substrate 100 are each in contact the corresponding first reflective portion 133 or make each of the side wall(s) of the light-emitting device 120 in the light-emitting substrate 100 and the corresponding first reflective portion 133 have a first gap GP1, thereby improving the area proportion of the reflective layer 130 in the light-emitting substrate 100. As a result, it is possible to improve the luminous efficiency of the light-emitting substrate 100, alleviate the problem of light and dark optical fringes and mura phenomenon of the light-emitting substrate 100, thereby improving the luminance of the backlight module 10 and the display apparatus 1, and reducing the power consumption of the backlight module 10 and the display apparatus 1.

For example, in a case where all the side walls of the light-emitting device 120 are each in contact with the corresponding first reflective portion 133, an area of an orthogonal projection of the first opening 131a on the substrate 110 may be substantially equal to an area of an orthographic projection of the corresponding light-emitting device 120 on the substrate 110, and a center of the orthogonal projection of the first opening 131a on the substrate 110 coincides with a center of the orthographic projection of the corresponding light-emitting device 120 on the substrate 110.

In the case where each of all the side walls of the light-emitting device 120 and the corresponding first reflective portion 133 have a first gap GP1 therebetween, the area of the orthogonal projection of the first opening 131a on the substrate 110 may be greater than the area of the orthographic projection of the corresponding light-emitting device 120 on the substrate 110, and the center of the orthogonal projection of the first opening 131a on the substrate 110 and the center of the orthographic projection of the corresponding light-emitting device 120 on the substrate 110 may or may not coincide with each other.

In a case where at least one side wall of the light-emitting device 120 is in contact with the corresponding first reflective portion 133, the area of the orthogonal projection of the first opening 131a on the substrate 110 may be greater than the area of the orthographic projection of the corresponding light-emitting device 120 on the substrate 110, and the center of the orthogonal projection of the first opening 131a on the substrate 110 does not coincide with the center of the orthographic projection of the corresponding light emitting device 120 on the substrate 110.

In some embodiments, as shown in FIG. 9g, forming the first reflective pattern RP1 in the first printing sub-region P11 by using the printing process in a surrounding manner includes: forming a plurality of first reflective sub-patterns RP11 in each first printing sub-region P11 sequentially by using the printing process in a surrounding manner. The plurality of first reflective sub-patterns RP11 are sequentially arranged in a direction away from the light-emitting device 120, and two adjacent first reflective sub-patterns RP11 partially overlap. The plurality of first reflective sub-patterns RP11 form the first reflective pattern RP1.

It will be understood that, in order to clearly illustrate the relative positional relationship (partial overlapping) of the two first reflective sub-patterns RP11, different types of fill patterns are performed on the two first reflective sub-patterns RP11 in FIG. 9g.

For example, the first reflective pattern RP1 is formed by sequentially stacking the plurality of first reflective sub-patterns RP11 that are formed by multiple printing processes. The greater the number of the first reflective sub-patterns RP11, the greater the area of the first reflective pattern RP1.

For example, in a case where the first reflective sub-pattern RP11 surrounds the corresponding light-emitting device 120, the shape of the first reflective sub-pattern RP11 is in a shape of an annulus surrounding the light-emitting device 120, and the first reflective pattern RP1 is composed of the plurality of first reflective sub-patterns RP11 that are stacked in an annulus manner.

For example, two adjacent first reflective sub-patterns RP11 partially overlap, which is beneficial to ensuring the thickness of the formed first reflective pattern RP1 (or the first reflective portion 133), thereby ensuring the reflectivity of the reflective layer 130 at this position.

With such the above arrangement, it may be possible to improve the shape accuracy of the reflective layer 130, which facilitates the accurate control of the relative position between the first reflective pattern RP1 and the light-emitting device 120, for example, being in contact with each other, or having a first gap GP1.

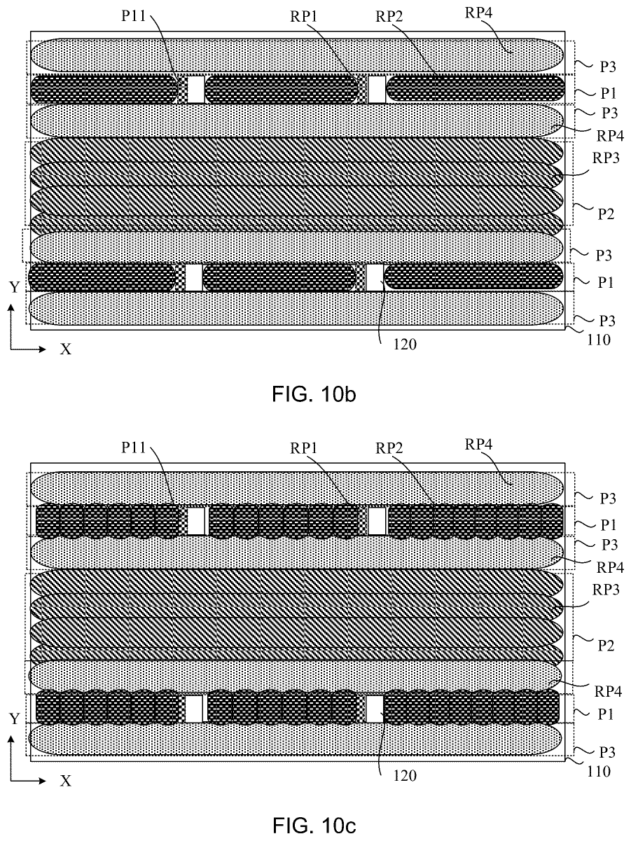

In some embodiments, as shown in FIG. 10a, the substrate 110 further has a plurality of third printing regions P3, and the third printing regions P3 are each located between a first printing region P1 and a second printing region P2.

For example, an extending direction of the third printing region P3 is the same as the extending direction of the second printing region P2.

Exemplarily, after forming the first reflective pattern RP1 in each first printing region P1 by using the printing process in a surrounding manner, the manufacturing method further includes S411.

In S411, as shown in FIG. 10b, a fourth reflective pattern RP4 is formed in the third printing region P3 by using the printing process in a straight-line manner.

For example, the side wall(s) of the first reflective pattern RP1 form one or more side walls of the first opening 131a.

In the case where the side wall(s) of the first reflective pattern RP1 form one side wall or two opposite side walls of the first opening 131a, the fourth reflective patterns RP4 may form one or two side walls of the first opening 131a.

For example, the fourth reflective pattern RP4 may be formed in the third printing region P3 by using the printing process in a straight-line manner after the second reflective pattern RP2 is formed. Alternatively, the process of forming the fourth reflective pattern RP4 in the third printing region P3 may be set before the second reflective pattern RP2 is formed.

In some embodiments, the second reflective patterns RP2, the third reflective patterns RP3 and the fourth reflective patterns RP4 form the second reflective portion 134 of the reflective layer 130.

In some examples, the second reflective pattern RP2, the third reflective pattern RP3, and the fourth reflective pattern RP4 have the same thickness. It can be seen from the above, the second reflective pattern RP2, the third reflective pattern RP3 and the fourth reflective pattern RP4 are formed by using the printing process in a dotted-line manner or the printing process in a straight-line manner. Moreover, the printing nozzles used in the printing process in a dotted-line manner and the printing process in a straight-line manner may spray substantially a same amount of reflective material. Therefore, the thickness of the second reflective portion 134 formed by connecting the second reflective pattern RP2, the third reflective pattern RP3 and the fourth reflective pattern RP4 has a small fluctuation.

In some examples, as shown in FIG. 8a, the thickness of the first reflective pattern RP1 is less than the thickness of the second reflective pattern RP2. It can be seen from the above, the first reflective pattern RP1 is formed by using the printing process in a surrounding manner; in a region within 100 μm from the light-emitting device, a printing process in a thin-layer manner (i.e., the printing process in a surrounding process) may be performed to improve the light interference problem of the light-emitting device 120. The first reflective pattern RP1 constitutes the first reflective portion 133. The thickness of the first reflective pattern RP1 is less than the thickness of the second reflective pattern RP2, and the thickness of the first reflective portion 133 is less than the thickness of the second reflective portion 134, so that the light consumption of the light-emitting device 120 may be small, and the light extraction efficiency of the light-emitting substrate 100 may be improved. As a result, the display brightness of the backlight module 10 and the display apparatus 1 is improved, and the power consumption of the backlight module 10 and the display apparatus 1 is reduced.

For example, a thickness of the reflective layer 130 may be in a range of 55 μm±5 μm. For example, the thickness of the reflective layer 130 is 50 μm, 52 μm, 55 μm, 57 μm or 60 μm.

Here, the thickness of the reflective layer 130 refers to an average thickness of the reflective layer 130.

Considering an example in which the thickness of the reflective layer 130 is 60 μm, the thickness of the first reflective pattern RP1 or the first reflective portion 133 may be less than 60 μm.

In some embodiments, as shown in FIG. 8a, the thickness of the first reflective portion 133 is positively correlated with a distance, in a direction Z1 passing through a center O of the light-emitting device 120 and perpendicular to a side wall of the light-emitting device 120, between the first reflective portion 133 and the center of the light-emitting device 120.

For example, the thickness of the first reflective portion 133 is not uniform, and the thicknesses of the first reflective portion 133 at different positions are different.

As shown in FIG. 8a, the greater a distance between a portion of the first reflective portion 133 and the center of the light-emitting device 120, the greater a thickness of the portion of the first reflective portion 133. The less a distance between a portion of the first reflective portion 133 and the center of the light-emitting device 120, the less the thickness of the portion of the first reflective portion 133. That is, in a direction towards the center of the light-emitting device 120 in FIG. 8a, the thickness of the first reflective portion 133 gradually decreases, reaching the minimum thickness at the portion closest to the light-emitting device 120.

In some embodiments, the minimum thickness of the first reflective portion 133 is less than 60 μm.

For example, the minimum thickness of the first reflective portion 133 may be 59 μm, 55 μm, 50 μm, 45 μm, or 40 μm.

With such the above arrangement, in a case where the first reflective portion 133 is in contact with one side of the light-emitting device 120, the proportion of light emitted from the path C may be reduced, thereby avoiding affecting the light extraction effect of the light-emitting device 120.

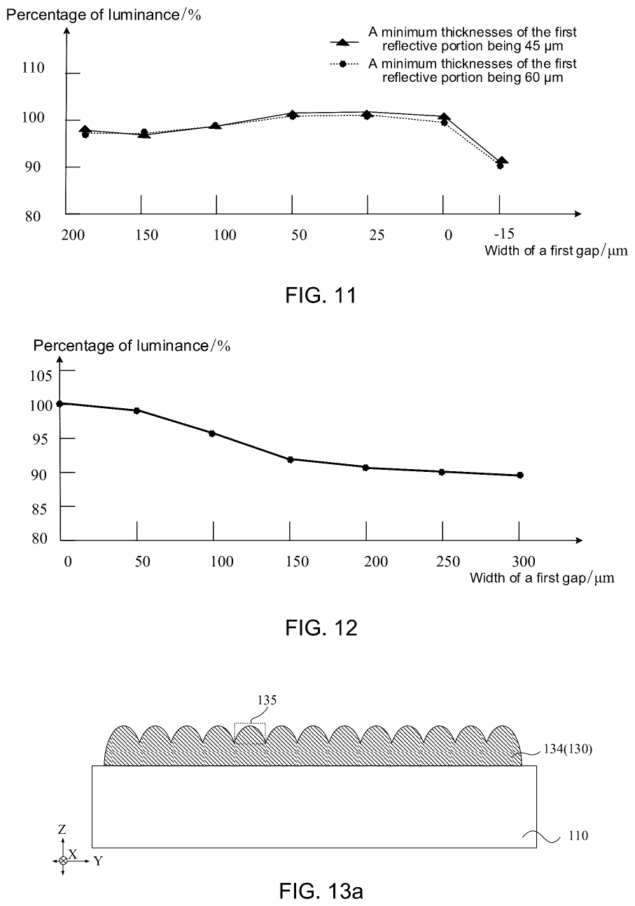

For cases in which the minimum thicknesses of the first reflective portion 133 are respectively 45 μm and 60 μm, and the widths of the first gaps GP1 between the first reflective portion 133 and the corresponding light-emitting device 120 are respectively 200 μm, 150 μm, 100 μm, 50 μm, 25 μm, and 0 μm, and the first reflective portion 133 covers a portion of the light-emitting device 120 (considering an example in which the first reflective portion covers a portion of the light-emitting device 120, and the dimension of the covered portion in the first direction is 15 μm, for convenience of description, the width of the first gap GP1 is-15 μm), the luminance of the light-emitting substrates 100 is simulated, and the simulation results are shown in FIG. 11. The above-mentioned “0 μm” represents the case where the first reflective portion 133 is in contact with the light-emitting device 120. The case in which the minimum thickness of the first reflective portion 133 is 60 μm is equivalent to an implementation in which there is no thickness difference between the first reflective portion and the second reflective portion, and the thickness of the first reflective portion is the same as the thickness of the second reflective portion.

As shown in FIG. 11, considering an example in which the luminance of the light-emitting substrate is 100% in a case where the thickness of the first reflective portion 133 is 60 μm and the light-emitting device 120 is in contact with the first reflective portion 133, as the width of the first gap GP1 is reduced from 150 μm to 0 μm, the luminance of the light-emitting substrate is gradually increased, and the fluctuation of the luminance is less than 5%, which is within the acceptable fluctuation range of the luminance; in a case where the width of the first gap GP1 is −15 μm, the luminance is reduced to about 90%, and the luminance fluctuates about 10%, which is within an unacceptable fluctuation range of the luminance. In a case where the width of the first gap GP1 is in the range of 0 μm to 150 μm, and the minimum thickness of the first reflective portion 133 is less than 60 μm, the fluctuation of the luminance of the light-emitting substrate 100 is acceptable.

In addition, a computer simulation is performed on the luminance of the light-emitting substrate in a case where the width of the first gap GP1 is gradually changed from 300 μm to 0 μm, and FIG. 12 is obtained. In FIG. 12, in a case where the width of the first gap GP1 is 0 μm, the luminance is 100%; in a case where the width of the first gap GP1 is 50 μm, the luminance is 98.9%; in a case where the width of the first gap GP1 is 100 μm, the luminance is 96.5%; in a case where the width of the first gap GP1 is 150 μm, the luminance is 95.0%; in a case where the width of the first gap GP1 is 200 μm, the luminance is 93.4%; in a case where the width of the first gap GP1 is 250 μm, the luminance is 91.6%; in a case where the width of the first gap GP1 is 300 μm, the luminance is 89.7%. In the implementation described above, the large-size light-emitting substrate is manufactured by the method: material preparation→forming the reflective layer by a screen printing process→AOI→die bonding→dot repair→AOI→encapsulation, it is possible to achieve that the gap between the reflective layer and the light-emitting device is in a range of 0.3 mm±0.15 mm (equivalent to the case where the width of the first gap is 300 μm). However, in the embodiments of the present disclosure, the width of the first gap GP1 may reach 0 μm; compared with the implementation, the luminance is increased from 89.7% to 100%, and the luminance gain is approximately 10%; moreover, in the light-emitting substrate 100 formed by the manufacturing method in the above embodiments of the present disclosure, the width of the first gap between the reflective layer 130 and the light-emitting device 120 may be controlled with an accuracy of 0.05 mm±0.05 mm, so that the luminance of the light-emitting substrate 100 may be greatly increased, and the energy consumption of the backlight module 10 and the display apparatus 1 may be reduced.

In some examples, as shown in FIG. 6e, the first reflective portion 133 includes a bottom surface 133p and a top surface 133t that are opposite to each other; the bottom surface 133p is in contact with the substrate 110, and an angle between the top surface 133t and a plane where the substrate 110 is located is an acute angle.

For example, the angle α between the top surface 133t and the plane where the substrate 110 is located may be 30°, 35°, 40°, 45° or 50°.

With such the above arrangement, as shown in FIG. 8a, the proportion of light emitted along the path C may be small, and the loss of light emitted by the light-emitting device 120 may be small, thereby increasing the reflectivity of the reflective layer 130, improving the luminous efficiency of the light-emitting substrate 100, and reducing the energy consumption of the backlight module 10 and the display apparatus.

In some embodiments, as shown in FIGS. 13a to 13c, the second reflective portion 134 includes a plurality of protruding structures 135, and the protruding structures 135 has a cambered surface on a side away from the substrate 110.

For example, the cambered surface protrudes outward in a direction away from the substrate 110.

With such the above arrangement, the uniformity of the light emitted by the reflective layer 130 may be improved.

It will be understood that the plurality of protruding structures 135 are unique morphological characteristics of the reflective layer 130 formed by the 3D printing. In the process of using a 3D printing device to print the reflective material to form the second reflective portion 134, multiple printing strips are printed, and two adjacent printing strips partially overlap to form a printing pattern. A portion of each printing strip that does not overlap with the adjacent printing strip forms the protruding structure 135 (the protruding structure 135 here does not include a third protruding structure 135c below).

It will be noted that the extending direction and arrangement of the protruding structures 135 are mainly determined by the printing path of the 3D printing process.

For example, as shown in FIG. 13a, in a case where the printing direction of the printing path of the 3D printing process is the first direction X, the plurality of protruding structures 135 each extend in the first direction X and are arranged in multiple rows in the second direction Y.

For example, in a case where the printing direction of the printing path of the 3D printing process is the second direction Y, the plurality of protruding structures 135 each extend in the second direction Y and are arranged in multiple columns in the first direction X.

In some examples, as shown in FIG. 13b, the protruding structures 135 include a plurality of first protruding structures 135a and a plurality of second protruding structures 135b.

For example, the plurality of first protruding structures 135a and the plurality of second protruding structures 135b may extend and may be arranged in various ways.

For example, as shown in FIG. 13b, the extending direction of the plurality of first protruding structures 135a and the extending direction of the plurality of second protruding structures 135b may be the same. The plurality of first protruding structures 135a each extend in the first direction X and are arranged in multiple rows in the second direction Y; the plurality of second protruding structures 135b each extend in the first direction X and are arranged in multiple rows in the second direction Y.

For another example, the extending direction of the plurality of first protruding structures 135a and the extending direction of the plurality of second protruding structures 135b may be different. The plurality of first protruding structures 135a each extend in the first direction X and are arranged in multiple rows in the second direction Y; the plurality of second protruding structures 135b each extend in the second direction Y and are arranged in multiple rows in the first direction X.

For example, the first protruding structure 135a may be a protruding structure formed by using a printing process in a straight-line manner, and the second protruding structure 135b may be a protruding structure formed by using a printing process in a dotted-line manner.

In some embodiments, the printing direction of the printing process in a straight-line manner and the printing direction of the printing process in a dotted-line manner are the same or perpendicular to each other.

For example, as shown in FIG. 10b, the printing direction of the printing process in a straight-line manner is the first direction X, and the printing direction of the printing process in a dotted-line manner is also the first direction X, and the two directions are the same. Here, the extending direction of each of the plurality of first protruding structures 135a and the extending direction of each of the plurality of second protruding structures 135b are the same.

For example, as shown in FIG. 10c, the printing direction of the printing process in a straight-line manner is the first direction X, and the printing direction of the printing process in a dotted-line manner is the second direction Y; the two directions are perpendicular to each other. Here, the extending direction of each of the plurality of first protruding structures 135a and the extending direction of each of the plurality of second protruding structures 135b are different.

For example, a dimension of the first protruding structure 135a in the second direction Y is the same as a dimension of the second protruding structure 135b in the arrangement direction of the plurality of second protruding structures 135b. That is, a width of a portion of each printing strip, formed by using the printing process in a straight-line manner, that does not overlap with the adjacent printing strip is the same as a width of a portion of each printing strip, formed by using the printing process in a dotted-line manner, that does not overlap with the adjacent printing strip.

In some embodiments, as shown in FIG. 13c, the plurality of protruding structures 135 further include third protruding structures 135c each located between two adjacent first protruding structures 135a; the third protruding structure 135c extends in the first direction X.

Exemplarily, the plurality of third protruding structures 135c are arranged in multiple rows in the second direction Y.

For example, the extending direction of the third protruding structure 135c is the same as the extending direction of the first protruding structure 135a that is adjacent to the third protruding structure 135c.

In some examples, a dimension W3 of the third protruding structure 135c in the second direction Y is less than a dimension W1 of the first protruding structure 135a in the second direction Y.

For example, the third protruding structure 135c is formed at the overlapping position of two adjacent printing strips. Therefore, the dimension W3 of the third protruding structure 135c in the second direction Y is much less than the dimension W1 of the first protruding structure 135a in the second direction Y.

For example, the physical morphological characteristics of the reflective layer 130 are as shown in FIGS. 13d, 13e, and 13f. The portions enclosed by dotted circles in FIGS. 13d and 13e are the morphology of the protruding structures. FIG. 13f shows “fish scale”-like grain on a surface of the reflective layer formed by multiple printing strips that are stacked.

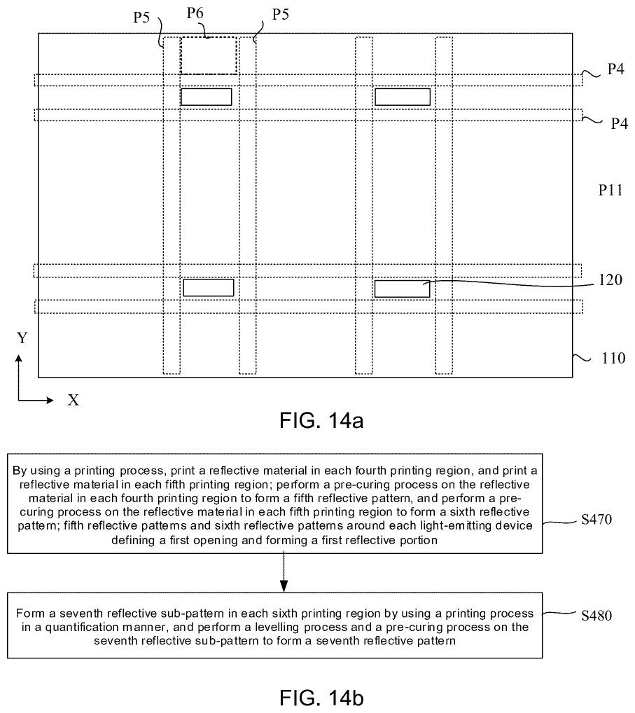

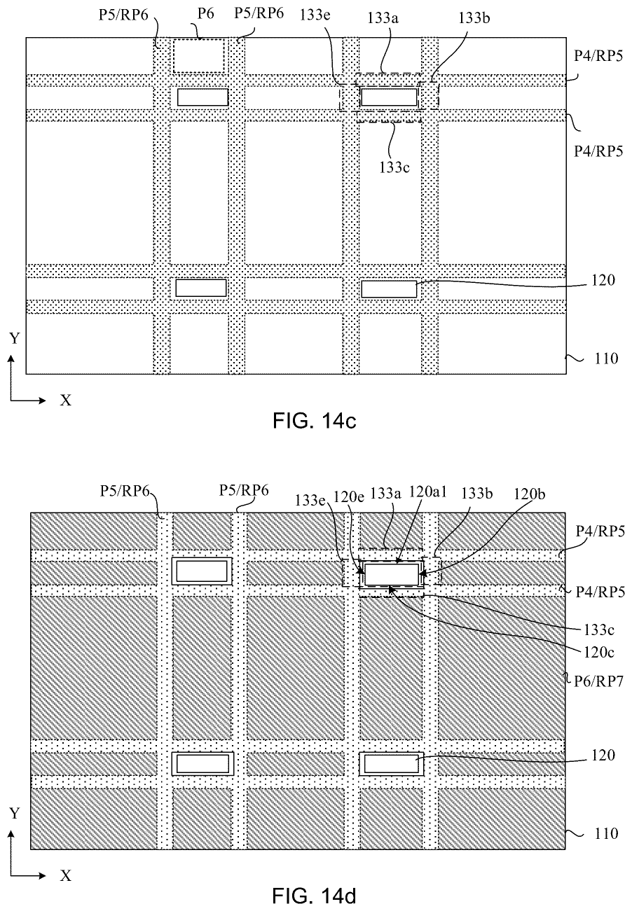

In some embodiments, as shown in FIG. 14a, the substrate 110 has a plurality of fourth printing regions P4 each extending in the first direction X, a plurality of fifth printing regions P5 each extending in the second direction Y, and a plurality of sixth printing regions P6. Two opposite sides of each row of light-emitting devices 120 are each provided with a fourth printing region P4; two opposite sides of each column of light-emitting devices are each provided with a fifth printing region P5; a region between any two adjacent light-emitting devices 120 excluding the fourth printing regions P4 and the fifth printing regions P5 is provided with a sixth printing region P6.

For example, the extending direction of each of the plurality of fourth printing regions P4 and the extending direction of each of the plurality of fifth printing regions P5 are perpendicular to each other, and the plurality of fourth printing regions P4 and the plurality of fifth printing regions P5 form a net-like structure, and the net-like structure includes a plurality of meshes. The plurality of meshes are arranged in rows in the first direction X, and are arranged in columns in the second direction Y. In every two rows of meshes, a row of meshes is provided with a row of light-emitting devices 120 therein, and the other row of meshes is provided with no light-emitting device 120.

In some examples, as shown in FIG. 14b, forming the reflective layer 130 on the substrate 110 by using a 3D printing process includes S470 to S480.

In S470, as shown in FIG. 14c, by using the printing process in a straight-line manner, the reflective material is printed in each fourth printing region P4, and the reflective material is printed in each fifth printing region P5; a pre-curing process is performed on the reflective material located in each fourth printing region P4 to form a fifth reflective pattern RP5, and a pre-curing process is performed on the reflective material located in each fifth printing region P5 to form a sixth reflective pattern RP6; the fifth reflective patterns RP5 and the sixth reflective patterns RP6 around each light-emitting device 120 define a first opening 131a and form a first reflective portion 133.

For example, the pre-curing process may be thermal curing.

Since the plurality of fourth printing regions P4 and the plurality of fifth printing regions P5 form a net-like structure, the plurality of fifth reflective patterns and the plurality of sixth reflective patterns intersect with each other to form a net-like structure.

For example, the first opening 131a defined by the fifth reflective pattern and the sixth reflective pattern around each light-emitting device 120 is in a shape of a rectangle. The first reflective portion 133 around the light-emitting device 120 is connected to the first reflective portion 133 around the adjacent light-emitting device 120.

In S480, as shown in FIG. 14d, a seventh reflective sub-pattern is formed in each sixth printing region P6 by using a printing process in a quantification manner, and a levelling process and a pre-curing process are performed on the seventh reflective sub-pattern to form a seventh reflective pattern RP7.

The printing process in a quantification manner means that a corresponding amount of reflective material is sprayed, by means of quantitative spraying, in the printing region according to an area of the region to be printed. That is, the area of the region to be printed is proportional to the amount of the reflective material sprayed by means of quantitative spraying. In a case where the areas of the regions to be printed are different, the amount of reflective material to be sprayed needs to be adjusted. Here, the amount of reflective material to be sprayed may be the mass or volume of the reflective material.

The reflective material to be printed has a certain viscosity, and a levelling process and a pre-curing process are performed on the seventh reflective sub-pattern. Thus, the thickness of the formed seventh reflective pattern RP7 is relatively uniform, so that a surface of the seventh reflective pattern RP7 away from the substrate 110 is relatively flat. Moreover, the seventh reflective pattern RP7 is formed by using the printing process in a quantification manner, which may ensure the uniformity of thickness in different regions of the reflective layer 130, thereby improving the reflectivity of the reflective layer 130.

In some embodiments of the present disclosure, the reflective layer 130 is formed by using the above method; firstly, a plurality of fifth reflective patterns RP5 and a plurality of sixth reflective patterns RP6 that are of a net-like structure are formed around each light-emitting device 120, and a bulge in a shape of a Chinese character “ [symbol] ” is formed around each light-emitting device 120; then, in a case where the printing process in a quantification manner is used, during the levelling process is performed on the seventh reflective sub-pattern in the sixth printing region P6, the reflective material will be blocked by the bulge in the shape of a Chinese character “ [symbol] ”, which prevents the reflective material from crossing the fifth reflective pattern RP5 and the sixth reflective pattern RP6 to reach the vicinity of the light-emitting device 120, so that it is possible to avoid affecting the welding performance of the light-emitting device 120 and to improve the shape accuracy of the reflective layer 130.

In some embodiments, as shown in FIG. 14d, in a case where the first reflective portion 133 surrounds the light-emitting device 120, and the orthographic projection of the light-emitting device 120 on the substrate 110 is in a shape of a rectangle, the light-emitting device 120 includes a first side wall 120a1, a second side wall 120b, a third side wall 120c and a fourth side wall 120e that are connected in sequence; the first side wall and the third side wall are opposite to each other and each extend in the first direction X; the second side wall and the fourth side wall are opposite to each other, and each extend in the second direction Y; the first reflective portion 133 includes a first reflective sub-portion 133a located on a side of the first side wall 120a1, a second reflective sub-portion 133b located on a side of the second side wall 120b, and a third reflective sub-portion 133c located on a side of the third side wall 120c, and a fourth reflective sub-portion 133e located on a side of the fourth side wall 120e.

For example, the first reflective portion 133 is in a shape of a rectangle in the top view. The center of the rectangle may or may not coincide with the center of the orthographic projection of the light-emitting device 120 on the substrate 110.

For example, the first side wall may be substantially parallel to the first reflective sub-portion 133a; the second side wall may be substantially parallel to the second reflective sub-portion 133b; the third side wall may be substantially parallel to the third reflective sub-portion 133c; the fourth side wall may be substantially parallel to the fourth reflective sub-portion 133e.

In some examples, multiple first reflective sub-portions 133a located on a side of the first side walls of the light-emitting devices 120 in a row are connected to form a one-piece structure. The multiple first reflective sub-portions 133a of the one-piece structure are formed by one fifth reflective pattern RP5.

In some examples, multiple second reflective sub-portions 133b located on a side of the second side walls of the light-emitting devices 120 in a column are connected to form a one-piece structure. The multiple first reflective sub-portions 133a of the one-piece structure are formed by one sixth reflective pattern RP6.

In some examples, multiple third reflective sub-portions 133c located on a side of the third side walls of the light-emitting devices 120 in a row are connected to form a one-piece structure. The multiple third reflective sub-portions 133c of the one-piece structure are formed by one fifth reflective pattern RP5.

In some examples, multiple fourth reflective sub-portions 133e located on a side of the fourth side walls of the light-emitting devices 120 in a column are connected to form a one-piece structure. The multiple first reflective sub-portions 133a of the one-piece structure are formed by one sixth reflective pattern RP6.

In some embodiments, before forming the reflective layer 130 on the substrate 110 by using a 3D printing process, the manufacturing method further includes S301a.

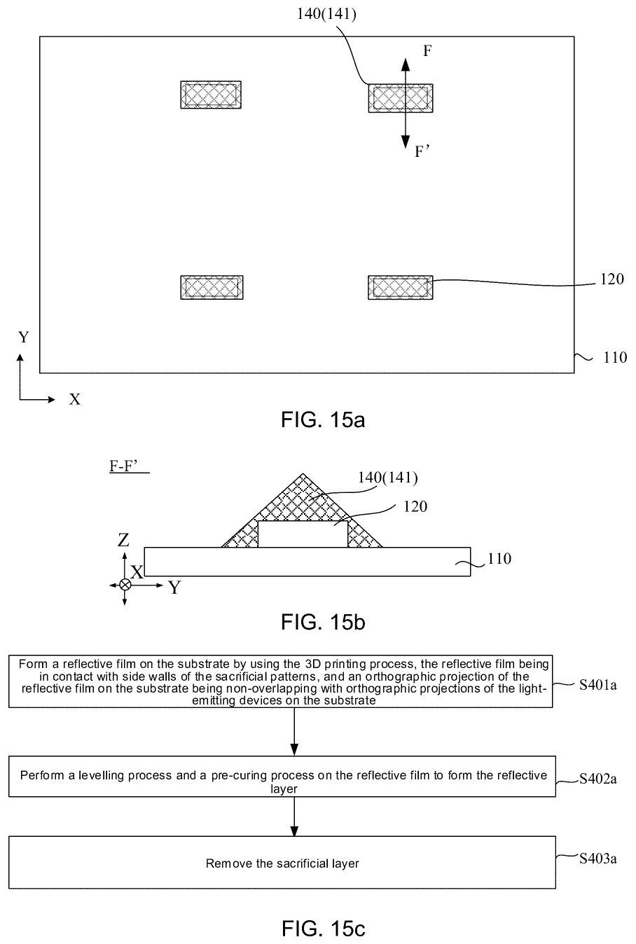

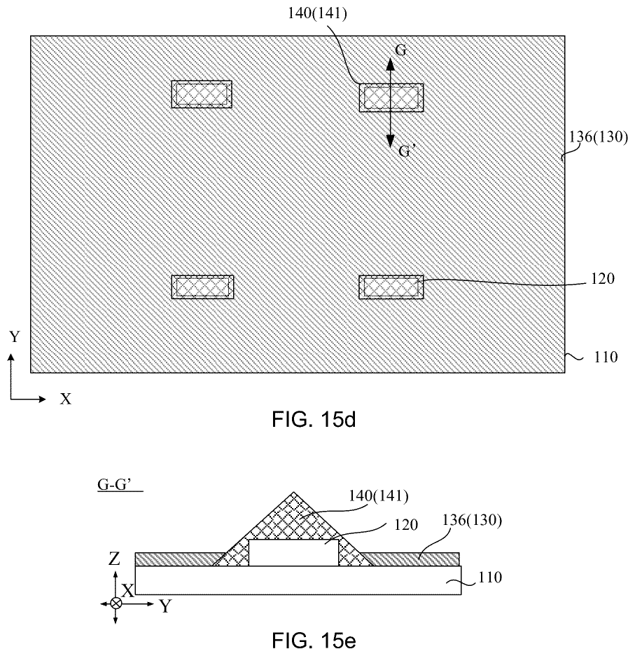

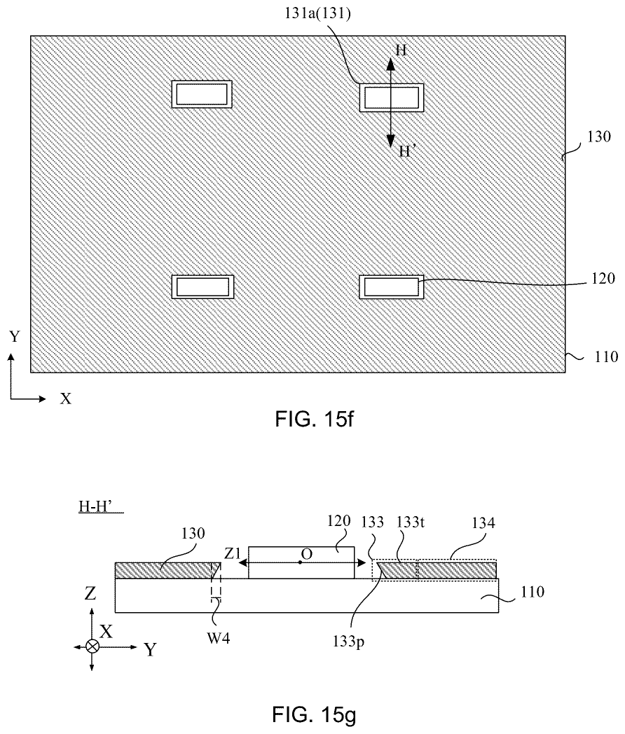

In S301a, as shown in FIGS. 15a and 15b, a sacrificial layer 140 is formed on a side of the plurality of light-emitting devices 120 away from the substrate 110. The sacrificial layer 140 includes a plurality of sacrificial patterns 141, and a sacrificial pattern 141 covers a top wall and side walls of a light-emitting device 120.

For example, a material of the sacrificial layer 140 may be selected from materials that does not react with the reflective material and can be removed by an oil-based or aqueous detergent.

For example, the plurality of sacrificial patterns 141 may be arranged in one-to-one correspondence with the plurality of light-emitting devices 120.

For example, the sacrificial layer 140 may be formed by using a 3D printing process; a quantitative spraying process is performed at the position corresponding to each light-emitting device 120 to form the sacrificial pattern 141. The plurality of sacrificial patterns 141 are not connected to each other.

For example, the sacrificial pattern 141 may be of a lens structure. The morphology of the lens structure of the formed sacrificial pattern may be controlled by adjusting the thixotropy of the material of the sacrificial layer.

For another example, after being sprayed onto the top wall of the light-emitting device 120, the sacrificial material (i.e., the material of the sacrificial layer 140) is in a shape of a hemisphere or substantially in a shape of a hemisphere, so that the surface of the formed sacrificial pattern 141 away from the substrate 110 also is substantially in a shape of a hemisphere.

The sacrificial pattern 141 covers all sides of the light-emitting device 120 except for the surface in contact with the substrate 110. Thus, in the subsequent process of forming the reflective film, it is possible to prevent the reflective material from overflowing onto the light-emitting device 120 or the pad, thereby preventing from affecting the luminous efficiency of the light-emitting device 120 and the welding performance between the light-emitting device 120 and the pad.

In some examples, as shown in FIG. 15c, forming the reflective layer 130 on the substrate 110 by using a 3D printing process includes S401a to S403a.

In S401a, as shown in FIGS. 15d and 15e, a reflective film 136 is formed on the substrate 110 by using a 3D printing process; the reflective film 136 is in contact with the side walls of the sacrificial patterns 141, and an orthographic projection of the reflective film 136 on the substrate 110 is non-overlapping with orthographic projections of the light-emitting devices 120 on the substrate 110.

Borders of the orthographic projection of the reflective film 136 on the substrate 110 do not intersect borders of the orthographic projections of the light-emitting devices 120 on the substrate 110.

For example, the reflective material is quantitatively sprayed on the region of the substrate 110 except for the sacrificial patterns 141 to form the reflective film 136.

For example, since the sacrificial pattern 141 wraps the light-emitting device 120, the reflective film 136 formed on the substrate 110 is separated from the light-emitting device 120 by the sacrificial pattern 141, so that there is a slight distance between the reflective film 136 and the light-emitting device 120.

In S402a, a levelling process and a pre-curing process are performed on the reflective film 136 to form the reflective layer 130.

For example, the reflective material is quantitatively sprayed at a fixed position, and there is a need to perform a levelling process on the reflective film 136 to enable the reflective material to gradually flow to a position that is in contact with the side wall of the sacrificial pattern 141, and then a thermal curing process is performed on the reflective film 136 to form the reflective layer 130, thereby ensuring that the reflective layer 130 has a relatively uniform thickness and ensuring the uniformity of the reflectivity of the reflective layer 130.

For example, the sacrificial layer 140 has a certain thickness, and the thickness is much greater than the thickness of the reflective layer 130. Thus, it may be possible to prevent the reflective material from climbing to the side wall of the sacrificial layer 140 during the levelling process for the reflective film 136, thereby preventing the reflective layer 130 from blocking the light-emitting devices 120.

In S403a, as shown in FIGS. 15f and 15g, the sacrificial layer 140 is removed.

For example, the sacrificial layer 140 may be removed by using a lipophilic remover or a hydrophilic lotion that is suitable for the material of the sacrificial layer 140 to form the first openings 131a.

With such the above manufacturing method, since the sacrificial layer 140 is manufactured in advance to cover the light-emitting devices 120, the process of spraying the reflective material is less restricted. Therefore, the manufacturing efficiency of the reflective layer 130 may be improved, and the manufacturing efficiency of the light-emitting substrate 100 may be improved.

In some examples, the manufacturing method for the light-emitting substrate 100 further includes S500.

In S500, an encapsulation process is performed on the light-emitting devices 120.

For example, as shown in FIG. 8a, an encapsulation layer 160 is formed by using an encapsulating adhesive to encapsulate the light-emitting device 120, thereby preventing the moisture from intruding into the interior of the light-emitting device 120 to prevent from affecting the light emission of the light-emitting device 120.

In some other embodiments, before forming the reflective layer 130 on the substrate 110 by using a 3D printing process, the manufacturing method further includes S301b.

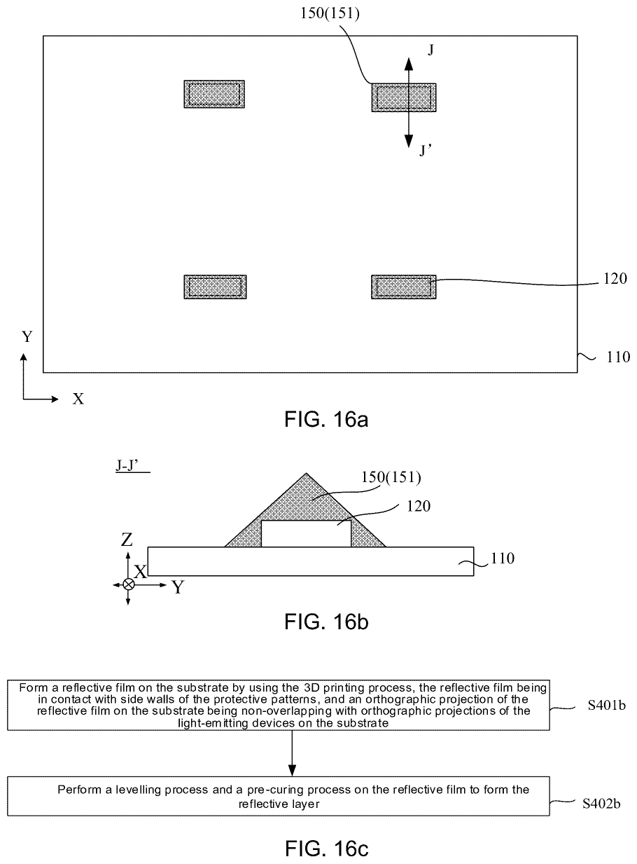

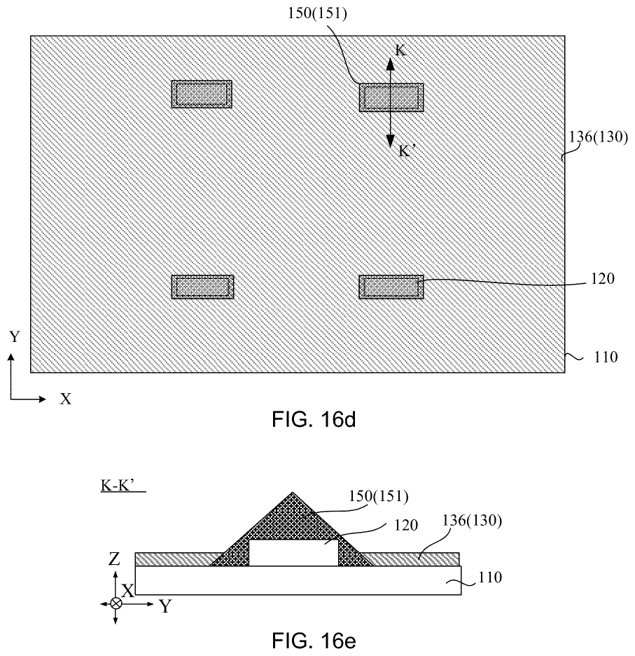

In S301b, as shown in FIGS. 16a and 16b, a protective layer 150 is formed on the side of the light-emitting devices 120 away from the substrate 110 by using a dispensing process; the protective layer 150 includes a plurality of protective patterns 151, and a protective pattern 151 covers the side walls and a top wall of a light-emitting device 120.

A material of the protective film 150 may be, for example, a transparent material.

For example, in the protective layer 150, the plurality of protective patterns 151 are not connected to each other, and the plurality of protective patterns 151 are independent of each other. The plurality of protective patterns 151 are in correspondence with the plurality of light-emitting devices 120.

For example, the protective pattern 151 may be in a shape of a hemisphere or substantially in a shape of a hemisphere.

For example, the protective pattern 151 may be of a lens structure.

For example, the protective pattern 151 covers all sides of the light-emitting device 120 except for the surface in contact with the substrate 110. Thus, in the subsequent process of forming the reflective film, it is possible to prevent the reflective material from overflowing onto the light-emitting device 120 or the pad, thereby preventing from affecting the luminous efficiency of the light-emitting device 120 and the welding performance between the light-emitting device 120 and the pad. In addition, the protective pattern 151 may protect the light-emitting device 120, so that the light-emitting device 120 is prevented from erosion by moisture and oxygen. The light emitted by the light-emitting device 120 passes through the protective pattern 151 and then exits. The hemispherical shape or lens structure of the protective pattern 151 may change the type of the light of the light-emitting device 120.

In some examples, as shown in FIG. 16c, forming the reflective layer on the substrate 110 by using the 3D printing process includes S401b to S402b.

In S401b, as shown in FIGS. 16d and 16e, a reflective film 136 is formed on the substrate 110 by using the 3D printing process; the reflective film 136 is in contact with side walls of the protective patterns 151, and an orthographic projection of the reflective film 136 on the substrate 110 is non-overlapping with the orthographic projections of the light-emitting devices 120 on the substrate 110.

Borders of the orthographic projection of the reflective film 136 on the substrate 110 do not intersect borders of the orthographic projections of the light-emitting devices 120 on the substrate 110.

For example, the reflective material is quantitatively sprayed on the region of the substrate 110 except for the protective patterns 151 to form the reflective film 136.

For example, since the protective pattern 151 wraps the light-emitting device 120, the reflective film 136 formed on the substrate 110 is separated from the light-emitting device 120 by the protective pattern 151, so that there is a slight distance between the reflective film 136 and the light-emitting device 120.

In S402b, as shown in FIGS. 16d and 16e, a levelling process and a pre-curing process are performed on the reflective film 136 to form the reflective layer 130.

For example, the reflective material is quantitatively sprayed at a fixed position, and there is a need to perform a levelling process on the reflective film 136 to enable the reflective material to gradually flow to a position that is in contact with the side wall of the protective pattern 151, and then a thermal curing process is performed on the reflective film 136 to form the reflective layer 130, thereby ensuring that the reflective layer 130 has a relatively uniform thickness and ensuring the uniformity of the reflectivity of the reflective layer 130.

For example, the protective layer 150 has a certain thickness, and the thickness is much greater than the thickness of the reflective layer 130. Thus, it may be possible to prevent the reflective material from climbing to the side wall of the protective layer 150 during the levelling process for the reflective film 136, thereby preventing the reflective layer 130 from blocking the light-emitting devices 120.

With such the above manufacturing method, the protective layer 150 may be reused as the encapsulation layer 160, thereby shortening the process flow of the light-emitting substrate 100.

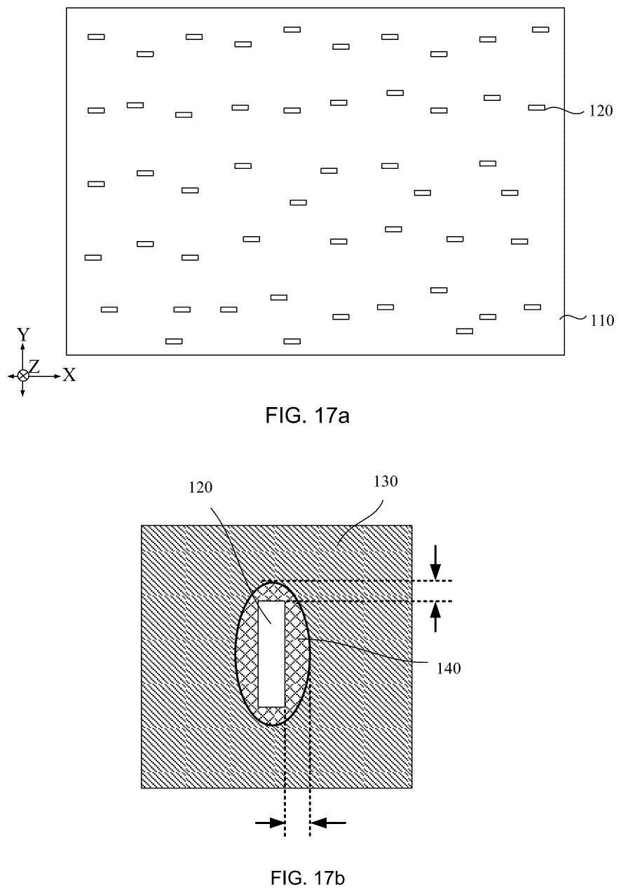

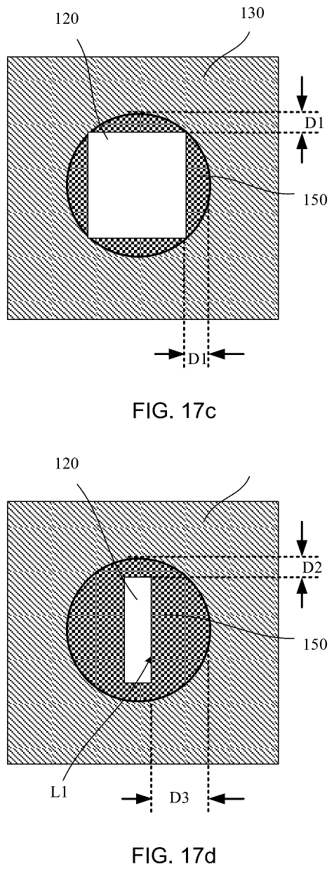

It will be understood that, for the light-emitting substrates 100 formed by the manufacturing methods in the two embodiments described above, there are no excessive restrictions on the arrangement of the light-emitting devices 120. The light-emitting devices 120 may be distributed in an irregular shape (as shown in FIG. 17a); that is, the light-emitting devices 120 are arranged in a non-array manner. Therefore, the light-emitting substrates 100 have wide application scenarios. The structures of the light-emitting substrates 100 respectively formed by the manufacturing methods in the above two embodiments will be introduced in detail below.

For example, a surface of the reflective layer 130 in contact with the sacrificial layer 140 constitutes a side wall of the first reflective portion 133. Therefore, the shape of the side wall of the sacrificial layer 140 determines the shape of the side wall of the first reflective portion 133. It can be seen from the above, the overall outline of the sacrificial pattern 141 is substantially in a shape of a hemisphere. Therefore, the side wall of the first reflective portion 133 in contact with the sacrificial pattern 141 has an approximate concave shape or a straight-line shape in the sectional view.

In some examples, as shown in FIG. 15g, the thickness of the first reflective portion 133 is positively correlated with a distance, in a direction Z1 passing through a center O of the light-emitting device 120 and perpendicular to a side wall of the light-emitting device 120, between the first reflective portion 133 and the center of the light-emitting device 120.

Exemplarily, in the sectional view (FIG. 15g) taken along the direction Z1 passing through the center O of the light-emitting device 120 and perpendicular to the side wall of the light-emitting device 120, the thickness of the first reflective portion 133 is not uniform, and the thickness of the first reflective portion 133 changes with the distance from the first reflective portion 133 to the center of the light-emitting device 120.

As shown in FIG. 15g, the greater a distance between a portion of the first reflective portion 133 and the center of the light-emitting device 120, the greater the thickness of the portion of the first reflective portion 133. The less a distance between a portion of the first reflective portion 133 and the center of the light-emitting device 120, the less the thickness of the portion of the first reflective portion 133. That is, in the direction from the first reflective portion 133 to the light-emitting device 120, the thickness of the first reflective portion 133 is gradually reduced, reaching the minimum thickness at the portion closest to the light-emitting device 120.

Exemplarily, the first reflective portion 133 includes a bottom surface 133p and a top surface 133t that are opposite to each other. At least portion of the bottom surface 133p is not in contact with the substrate 110, and an angle between the at least portion of the bottom surface 133p and a plane where the substrate 110 is located is an acute angle. The top surface 133t is parallel to or substantially parallel to the plane where the substrate 110 is located.

For example, as shown in FIG. 15g, in a case where a portion of the bottom surface 133p of the first reflective portion 133 is not in contact with the substrate 110, the first reflective portion 133 may be in a shape of a trapezoid in the sectional view. Here, the trapezoid is a non-strictly defined trapezoid.

For another example, in a case where the entire bottom surface 133p of the first reflective portion 133 is not in contact with the substrate 110, the first reflective portion 133 may be in a shape of a triangle in the sectional view. Here, the triangle is a non-strictly defined triangle.

Here, the top surface of the first reflective portion 133 is parallel to or substantially parallel to the plane where the substrate 110 is located, which is a morphological characteristic of the reflective layer 130 formed after a levelling process is performed on the reflective film 136 in the above manufacturing method. Thus, the reflectivity of the top surface of the first reflecting portion 133 may be improved.

In some examples, as shown in FIG. 15g, in the direction passing through the center of the light-emitting device 120 and perpendicular to the side wall of the light-emitting device 120, a dimension W4 of the portion of the first reflective portion 133 that is not in contact with the substrate 110 is less than 20 μm.

For example, in the sectional view (FIG. 15g) taken along the direction passing through the center of the light-emitting device 120 and perpendicular to the side wall of the light-emitting device 120, the dimension W4 of the portion of the first reflective portion 133 that is not in contact with the substrate 11 may be 19 μm, 16 μm, 13 μm, 10 μm or 5 μm.

It has been verified by experiments that in a case where the dimension W4 of the portion of the first reflective portion 133 that is not in contact with the substrate 11 is less than 20 μm, it may be ensured that the morphology of the reflective layer 130 meets the optical requirements and the reflectivity of the reflective layer 130 is high.

In some examples, a surface of the second reflective portion 134 away from the substrate 110 may be a flat surface or may substantially be a flat surface.

For example, the thickness of the second reflective portion 134 is relatively uniform.

For example, the flat surface may improve the reflectivity of the reflective layer 130.

It can be seen from the above, the top surface of the first reflective portion 133 is parallel to the plane where the substrate 110 is located. Therefore, the top surface of the first reflective portion 133 may be located on the same horizontal plane as the surface of the second reflective portion 134 away from the substrate 110, so that the surface of the reflective layer 130 away from the substrate 110 may be relatively flat, and the first reflective portion 133 and the second reflective portion 134 of the reflective layer 130 may be formed in a single manufacturing process, so as to simplify the manufacturing process of the reflective layer 130.

It can be understood that in a case where the size of the light-emitting device 120 is different, the reflective layer 130 is formed by using a different manufacturing process. For example, in FIG. 17c, in a case where of the light-emitting device 120 is in a shape of a square in the top view, and the side length of the square is 0.45 mm, a condition that the distance D1 between the side wall of the light-emitting device and the reflective layer 130 is in the range of 0.1 mm may meet the optical requirements. Therefore, it is necessary to set the diameter of the protective layer (considering an example in which the protective layer 150 is in a shape of a hemisphere) to be approximately 0.65 mm. In this case, the distance between each side of the square (i.e., each side wall of the light-emitting device) and the reflective layer 130 is approximately 0.1 mm. Therefore, the light-emitting substrate 100 in which light-emitting device 120 is in a shape of a square with a side length of 0.45 mm in the top view may be formed by first forming the protective layer 150 and then forming the reflective layer 130. For another example, in FIG. 17d, in a case where the light-emitting device 120 is in a shape of a rectangle in the top view, a length of the long side L1 is 0.52 mm, and a length of the short side is 0.15 mm, the diameter of the protective layer 150 needs to be set 0.72 mm. In this case, the distance D2 between the short side and the reflective layer 130 is 0.1 mm, while the distance D3 between the long side and the reflective layer 130 is greater than 0.1 mm, resulting in a great distance between each of two side walls of the light-emitting device 120 and the reflective layer, which easily causes the problems of light leakage and the reduction of the reflectivity. Therefore, the light-emitting substrate 100 in which the light-emitting device is in a shape of a rectangle is not suitable for using the method of first forming the protective layer 150 and then forming the reflective layer 130, but is suitable for using the method of first forming the sacrificial layer 140, forming a reflective film and then removing the sacrificial layer 140 (as shown in FIG. 17b).

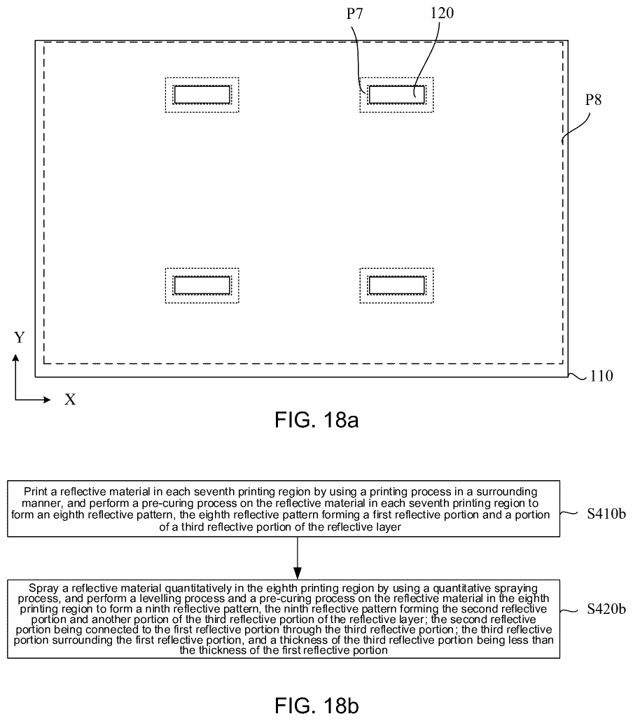

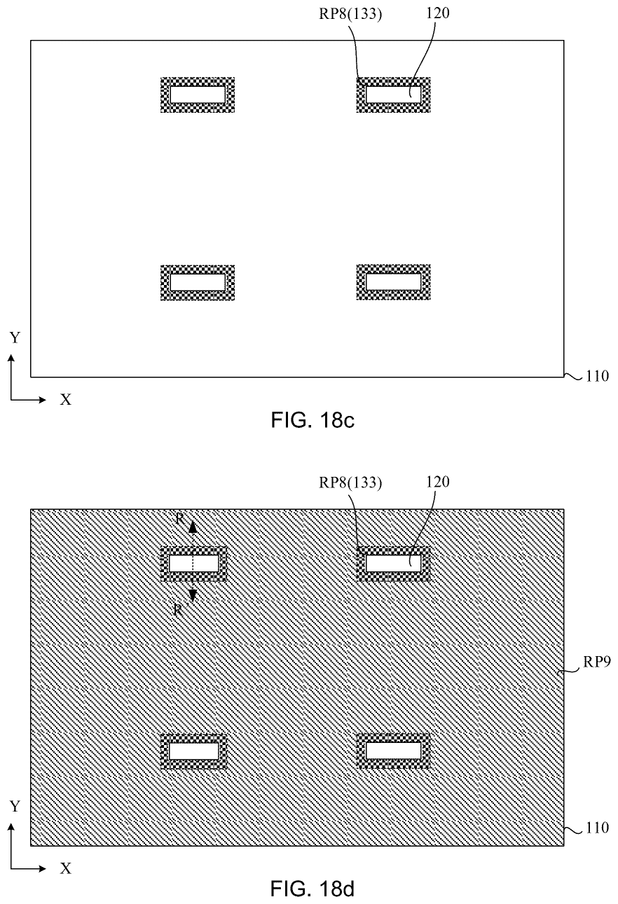

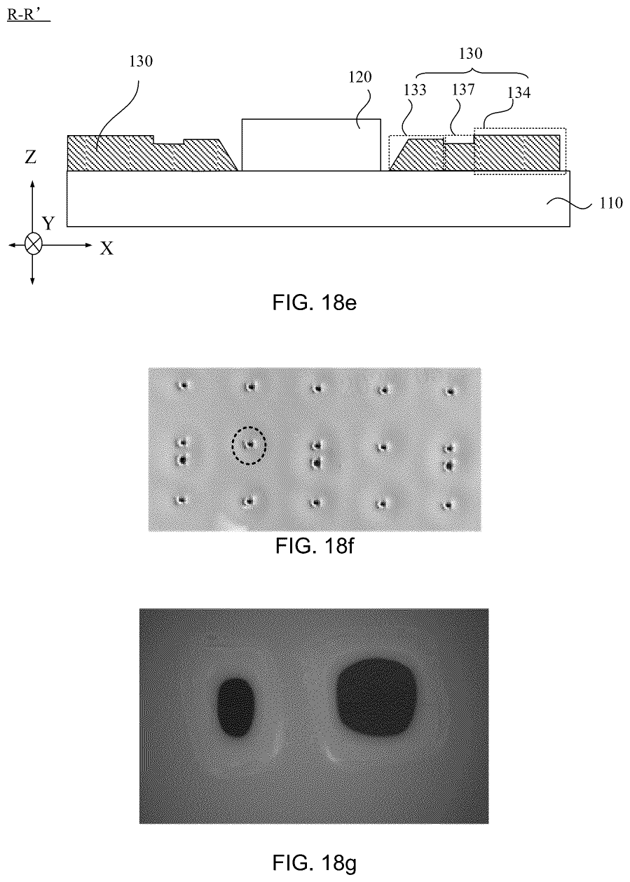

In some embodiments, as shown in FIG. 18a, the substrate 110 has a plurality of seventh printing regions P7 and an eighth printing region P8. The seventh printing region P7 surrounds the light-emitting device 120, and the eighth printing region P8 is located between any two adjacent seventh printing regions P7.

For example, the plurality of seventh printing regions P7 are in one-to-one correspondence with the plurality of light-emitting devices 120, and a seventh printing region P7 corresponds to a light-emitting device 120.

For example, in a case where the plurality of light-emitting devices 120 are arranged in an array, the plurality of seventh printing regions P7 are arranged in an array accordingly.

In some examples, as shown in FIG. 18b, forming the reflective layer 130 on the substrate 110 by using a 3D printing process includes S410b to S420b.

In S410b, as shown in FIG. 18c, a reflective material is printed in each seventh printing region P7 by using a printing process in a surrounding manner, and a pre-curing process is performed on the reflective material in each seventh printing region P7 to form an eighth reflective pattern RP8; the eighth reflective pattern RP8 forms the first reflective portion 133 and a portion of the third reflective portion 137 of the reflective layer 130.

The eighth reflective pattern is formed by using the printing process in a surrounding manner, the distance between the reflective layer 130 and the light-emitting device 120 may be accurately controlled, thereby increasing the reflectivity of the reflective layer 130 and improving the luminance of the light-emitting substrate 100.

In S420b, as shown in FIGS. 18d and 18e, a reflective material is quantitatively sprayed in the eighth printing region P8 by using a quantitative spraying process, and a levelling process and a pre-curing process are performed on the reflective material in the eighth printing region P8 to form a ninth reflective pattern RP9. The ninth reflective pattern RP9 forms the second reflective portion 134 and another portion of the third reflective portion 137 of the reflective layer 130.

For example, the third reflective portion 137 is located between the first reflective portion 133 and the second reflective portion 134, and the second reflective portion 134 is connected to the first reflective portion 133 through the third reflective portion 137.

For example, the first reflective portion 133 surrounds the light-emitting device 120, and the third reflective portion 137 surrounds the first reflective portion 133.

For example, a 3D printing device may be equipped with two different printing heads. The first print head may achieve high-precision detail printing and is used in the printing process in a surrounding manner. The first printing head may print a rectangular frame-shaped reflective material with a certain thickness with high precision in the seventh printing region P7, and then a pre-curing process is performed to form an eighth reflective pattern, so that the eighth reflective pattern may block the reflective material in the eighth printing region P8 to prevent the reflective material in the eighth printing region P8 from levelling to the vicinity of the seventh printing region P7 and the light-emitting region 120. As a result, the shape accuracy of the reflective layer 130 may be ensured. The second printing head may perform a quantitative spray process to spray the reflective material in the eighth printing region P8.

Exemplarily, in the reflective layer 130 manufactured by the above method, a “coffee ring” visible to the human eye is formed at the edge of the rectangular frame (as shown in FIGS. 18f and 18g) mentioned above. That is, a thickness of a portion of the reflective layer 130 located within a certain range around the rectangular frame (approximately 1 mm from the rectangular frame) is less than a thickness of a portion of the reflective layer 130 located in the rectangular frame, and the difference between the thicknesses is approximately 10 μm.

For example, the relative position of the “coffee ring” and the light-emitting device 120 and the thickness difference may be controlled by controlling the thickness of the printed rectangular frame, printing time, pre-curing conditions, and the like to make the reflectivity of the reflective layer 130 high.

For example, a pre-curing process is performed on the reflective material at the position of the rectangular frame to form the first reflective portion 133 and a portion of the third reflective portion 137 of the reflective layer 130. A portion, in contact with the eighth reflective pattern RP8, of the ninth reflective pattern RP9 forms another portion of the third reflective portion 137, and the remaining portion forms the second reflective portion 134.

For example, the thickness of the third reflective portion 137 is less than the thickness of the first reflective portion 133.

For example, as shown in FIG. 18e, the thickness of the first reflective portion 133 is 50 μm, the thickness of the third reflective portion 137 is 45 μm, and the thickness of the second reflective portion 134 is 55 μm.

The thickness of the first reflective portion 133 refers to the maximum thickness of the first reflective portion 133.

It will be understood that the morphological characteristic of the “coffee ring” in the reflective layer 130 are the unique morphology of the reflective layer formed by the manufacturing method provided in the embodiments of the present disclosure.

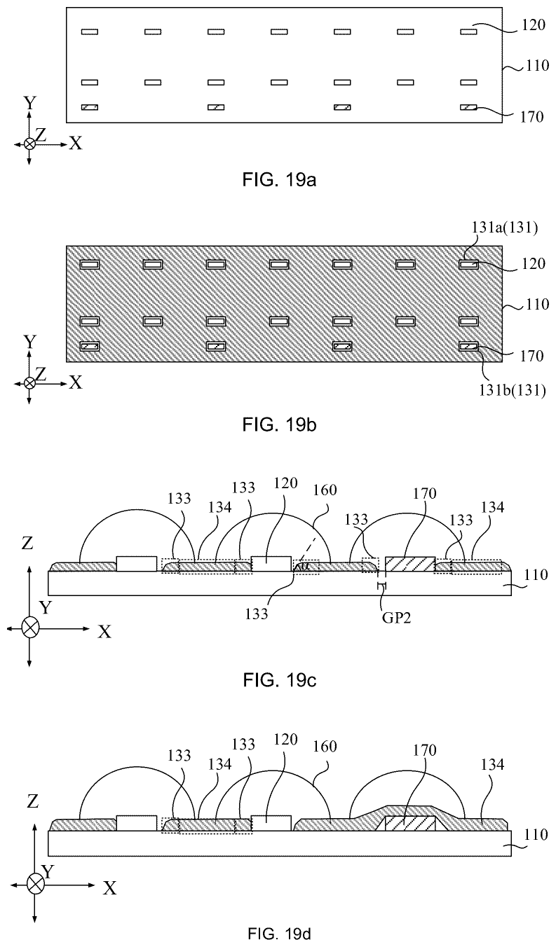

It will be understood that, as shown in FIGS. 19a to 19d, the light-emitting substrate 100 further includes a plurality of driver chips 170.

In some examples, a driver chip 170 is electrically connected to at least one light-emitting device 120, and the driver chip 170 is configured to drive the at least one light-emitting device 120 to emit light.

For example, a driver chip 170 is electrically connected to a light-emitting device 120 to drive the light-emitting device 120 to emit light.

For example, as shown in FIGS. 6c and 19a, a driver chip 170 may be electrically connected to four light-emitting devices 120 to drive the four light-emitting devices 120 to emit light.

For example, a driver chip 170 may be electrically connected to nine light-emitting devices 120 to drive the nine light-emitting devices 120 to emit light.

The description will be made by taking an example in which a driver chip 170 drives four light-emitting devices 120.

The following description will be made by taking an example in which four light-emitting devices driven by a driver chip 170 are arranged in two rows and two columns, and the driver chip 170 is located directly below the light-emitting devices 120 in any column.

There are two relative positional relationships between the driver chip 170 and the reflective layer 130, i.e., the driver chip(s) 170 are located in respective openings 131, and the driver chip(s) 170 are covered by the reflective layer 130. The light-emitting substrates 100 corresponding to the above two positional relationships respectively will be manufactured by different manufacturing methods, which will be described separately below.

For the case where the driver chip 170 is located in the opening 131, in the above manufacturing method, before cleaning the portion of the substrate 110 located around each light-emitting device 120, the manufacturing method of the light-emitting substrate 100 further includes S210.

In S210, as shown in FIG. 19a, a plurality of driver chips 170 are fixed on the substrate 110.

Correspondingly, after cleaning the portion of the substrate 110 located around each light-emitting device 120, the method for manufacturing the light-emitting substrate 100 further includes S301.

In S301, the portion of the substrate 110 located around each driver chip 170 is cleaned.

For example, for the cleaning process of cleaning the surrounding region of the driver chip 170, reference may be made to the above-mentioned cleaning process of cleaning the surrounding region of the light-emitting device 120, which will not be repeated here.

In some embodiments, as shown in FIG. 19b, the plurality of openings 131 of the reflective layer 130 further include a plurality of second opening 131b.

In some examples, the plurality of driver chips 170 are in one-to-one correspondence with the plurality of second openings 131b, and a driver chip 170 is located in a second opening 131b.

For example, the size of the first opening 131a is related to the size of the light-emitting device 120, and the size of the second opening 131b is related to the size of the driver chip 170. Therefore, the size of the first opening 131a and the size of the second opening 131b may be the same or different. The shape of the first opening 131a in the top view may be the same as or different from the shape of the second opening 131b in the top view.

For example, the first reflective portion 133 is located on at least one side of the driver chip 170.

In some examples, the first reflective portion 133 is located on at least one side of the driver chip 170 in various manners. For example, the first reflective portion 133 may be located on a side of the driver chip 170. For another example, the first reflective portion 133 may be located on two adjacent sides or two opposite sides of the driver chip 170. For another example, the first reflective portion 133 may surround the corresponding driver chip 170.

In the above embodiment, as shown in FIG. 19c, at least one side wall of the driver chip 170 is in contact with the corresponding first reflective portion 133, and/or at least one side wall of the driver chip 170 and the corresponding first reflective portion 133 have a second gap GP2 therebetween.

In some examples, at least one side wall of the driver chip 170 is in contact with the corresponding first reflective portion 133.

For example, one side wall or multiple side walls of the driver chip 170 are each in contact with the corresponding first reflective portion 133.

Considering an example in which the driver chip 170 is in a shape of a rectangle in the top view, it may be possible that one side wall of the driver chip 170 is in contact with the first reflective portion 133 (each of the other three side walls and the first reflective portion 133 may have a second gap therebetween); alternatively, it is possible that four side walls of the driver chip 170 are each in contact with the first reflecting portion 133.

In the embodiments of the present disclosure, the light-emitting substrate 100 is manufactured by using the above manufacturing method, the portion of the substrate 110 located around each driver chip 170 is cleaned, which alleviates the repelling phenomenon occurring between the portion of the substrate located around the driver chip 170 and the reflective material that needs to be printed in the subsequent process, so that the side wall of the driver chip 170 is in contact with the corresponding first reflective portion 133 in the light-emitting substrate 100. As a result, it is possible to increase the area proportion of the reflective layer 130 in the light-emitting substrate 100, which may improve the luminous efficiency of the light-emitting substrate 100, and alleviate the problem of light leakage, light and dark optical fringes, and mura phenomenon of the light-emitting substrate 100, thereby improving the luminance of the backlight module 10 and the display apparatus 1, and reducing the power consumption of the backlight module 10 and the display apparatus 1.

In some other examples, there is a second gap GP2 between at least one side wall of the driver chip 170 and the corresponding first reflective portion 133.

For example, there is a second gap GP2 between one side wall or each of multiple side walls of the driver chip 170 and the corresponding first reflective portion 133.

Considering an example in which the driver chip 170 is in a shape of a rectangle in the top view, there may be a second gap GP2 between one side wall of the driver chip 170 and the first reflective portion 133; alternatively, there may be a second gap GP2 between each of the four side walls of the driver chip 170 and the first reflective portion 133, and the distance between each of the four side walls and the first reflective portion 133 is the same.

For example, the width of the second gap GP2 is less than or equal to 150 μm.

For example, the width of the second gap GP2 refers to a dimension of the second gap GP2 in a direction perpendicular to the side wall of the corresponding light-emitting device 120.

For example, the width of the second gap GP2 may be 150 μm, 100 μm, 50 μm, 25 μm or 10 μm.

It will be understood that the width of the second gap GP2 and the width of the first gap GP1 may be the same or different.

In the embodiments of the present disclosure, the light-emitting substrate 100 is manufactured by using the above manufacturing method, the portion of the substrate 110 located around each driver chip 170 is cleaned, which alleviates the repelling phenomenon occurring between the portion of the substrate located around the driver chip 170 and the reflective material that needs to be printed in the subsequent process, so that the width of the second gap between the side wall of the driver chip 170 and the corresponding first reflective portion 133 in the light-emitting substrate 100 is small. As a result, it is possible to increase the area proportion of the reflective layer 130 in the light-emitting substrate 100, which may improve the luminous efficiency of the light-emitting substrate 100, and alleviate the problem of light and dark optical fringes and mura phenomenon of the light-emitting substrate 100, thereby improving the luminance of the backlight module 10 and the display apparatus 1, and reducing the power consumption of the backlight module 10 and the display apparatus 1.

In some other examples, at least one side wall of the driver chip 170 is in contact with the corresponding first reflective portion 133, and there is a second gap GP2 between another at least one side wall of the driver chip 170 and the corresponding first reflective portion 133.

For example, one side wall of the driver chip 170 is in contact with the corresponding first reflective portion 133, and there is a second gap GP2 between each of the remaining side walls of the driver chip 170 and the corresponding first reflective portion 133.

For another example, there is a second gap GP2 between one side wall of the driver chip 170 and the corresponding first reflecting portion 133, and the remaining side walls of the driver chip 170 are each in contact with the corresponding first reflecting portion 133.

For another example, there is a second gap GP2 between each of two side walls of the driver chip 170 and the corresponding first reflecting portion 133, and the remaining side walls of the driver chip 170 are each in contact with the corresponding first reflecting portion 133.

In the embodiments of the present disclosure, the light-emitting substrate 100 is manufactured by using the above manufacturing method, the portion of the substrate 110 located around each driver chip 170 is cleaned, which alleviates the repelling phenomenon occurring between the portion of the substrate located around the driver chip 170 and the reflective material that needs to be printed in the subsequent process, so that the side wall(s) of the driver chip 170 in the light-emitting substrate 100 are each in contact with the corresponding first reflective portion 133 or there is a second gap with a small width between each of the side wall(s) of the driver chip 170 and the corresponding first reflective portion 133 in the light-emitting substrate 100. As a result, it is possible to increase the area proportion of the reflective layer 130 in the light-emitting substrate 100, which may improve the luminous efficiency of the light-emitting substrate 100 and alleviate the problem of light and dark optical fringes and mura phenomenon of the light-emitting substrate 100, thereby improving the luminance of the backlight module 10 and the display apparatus 1 and reducing the power consumption of the backlight module 10 and the display apparatus 1.

As shown in FIG. 19d, for the case where the driver chip(s) 170 are covered by the reflective layer 130, which may include the case in which an orthographic projection of at least one driver chip 170 on the substrate 110 is located within the orthographic projection of the reflective layer 130 on the substrate 110. That is, at least one driver chip 170 is covered by the reflective layer 130, and the remaining driver chips 170 may be located in the respective second openings 131b of the reflective layer 130.

For example, a border of an orthographic projection of a driver chip 170 on the substrate 110 is within the border of the orthogonal projection of the reflective layer 130 on the substrate 110.

For another example, the borders of the orthographic projections of the plurality of driver chips 170 on the substrate 110 are all within the border of the orthographic projection of the reflective layer 130 on the substrate 110.

With such the above arrangement, the area proportion of the reflective layer 130 in the light-emitting substrate 100 may be increased, and the area of the reflective region of the light emitted by the light-emitting device 120 may be increased, thereby improving the luminous efficiency of the light-emitting substrate 100 and alleviating the problem of light leakage of the light-emitting substrate 100.

It will be understood that, in a case where the first reflective portion 133 is located on at least one side of the driver chip 170, as for the manufacturing methods of the reflective layer 130 and the light-emitting substrate 100, reference may be made to the manufacturing method of the case in which the first reflective portion 133 is located on at least one side of the light-emitting device 120, which will not be repeated here.

Some embodiments of the present disclosure provide a light-emitting substrate 100, and the light-emitting substrate 100 is a light-emitting substrate manufactured by the manufacturing method as described in any one of the above embodiments.

The structure of the light-emitting substrate 100 will be described below.

In some examples, as shown in FIGS. 2 and 3, the light-emitting substrate 100 includes a substrate 110, light-emitting devices 120 and a reflective layer 130.

In some examples, the plurality of light-emitting devices 120 are disposed on a side of the substrate 110.

In some examples, as shown in FIG. 6e, the reflective layer 130 includes a plurality of first reflective portions 133 and a second reflective portion 134 connecting any two adjacent first reflective portions 133. The first reflective portion 133 is located on at least one side of the light emitting device 120. A thickness of the first reflective portion 133 is less than a thickness of the second reflective portion 134.

For example, the first reflective portion 133 is closer to the light-emitting device 120 than the second reflective portion 134.

In some examples, the first reflective portion 133 is located on at least one side of the light-emitting device 120, and the arrangement may vary.

For example, the first reflective portion 133 may be located on one side of the light-emitting device 120.

For another example, the first reflective portion 133 may be located on two adjacent sides or two opposite sides of the light-emitting device 120.

For another example, the first reflective portion 133 may be located on three sides of the light-emitting device 120.

For another example, the first reflective portion 133 may surround the corresponding light-emitting device 120.

For example, an orthogonal projection of the light-emitting device 120 on the substrate 110 may have various shapes, such as a circle or a rectangle.

The thickness of the first reflective portion 133 is small, so that the shape accuracy of the first reflective portion is easy to be controlled. For the rectangular light-emitting device 120, compared with the shape accuracy of the portion of the first reflective portion 133 corresponding to the short side, the shape accuracy of the portion of the first reflective portion 133 corresponding to the long side has a greater impact on the luminous efficiency of the light-emitting substrate 100. Therefore, in a case where the first reflective portion 133 is located on two opposite sides of the light-emitting device 120, and the orthographic projection of the light-emitting device 120 on the substrate 110 is in a shape of a rectangle, the first reflective portion 133 is located on sides of the two long sides of the rectangle. Thus, the luminous efficiency of the light-emitting substrate 100 may be improved, the printing cost of the reflective layer 130 may be reduced, and the printing efficiency of the reflective layer 130 may be improved.

It will be understood that, as shown in FIG. 8a, the luminous efficiency of the light-emitting substrate is related to the light exit mode of the light-emitting device. There are three paths for the light emitted by the light-emitting device 120 to exit. The light emitted by the light-emitting device 120 is emitted through the path A and the path B, i.e., the light is emitted directly from the top wall or side wall of the light-emitting device 120 without passing through the reflective layer 130, resulting in a less loss of light. The light emitted by the light-emitting device 120 is emitted through the path C, i.e., the light is reflected by the side wall of the first reflective portion 133 and then emitted from the side wall of the light-emitting device 120, resulting in a great loss of light. The greater the proportion of light emitted from the path C, the greater the loss of light of the light-emitting device, and the less the light extraction efficiency of the light-emitting substrate. In the embodiments of the present disclosure, the thickness of the first reflective portion 133 is set to be less than the thickness of the second reflective portion 134, which may ameliorate the situation where light is reflected on the side walls of the first reflective portion 133 and then emitted, so that the light emitted through the path C accounts for a small proportion of the light emitted by the light-emitting device 120. As a result, the loss of light of the light-emitting device 120 is small, which may improve the light extraction efficiency of the light-emitting substrate 100, thereby improving the display brightness of the backlight module 10 and the display apparatus 1, and reducing the power consumption of the backlight module 10 and the display apparatus 1.

There are various positional relationships between the side walls of the light-emitting device 120 and the corresponding first reflective portion 133, which may be set according to actual needs, and is not limited in the present disclosure

In a case where the light-emitting device 120 has a plurality of side walls, the relative positional relationship between each of the plurality of side walls of the light-emitting device 120 and the corresponding first reflective portion 133 may be the same or different.

In some embodiments, as shown in FIG. 9f, at least one side wall of the light-emitting device 120 and the corresponding first reflective portion 133 have a first gap GP1 therebetween, and/or at least one side wall of the light-emitting device 120 is in contact with the corresponding first reflective portion 133.

In some examples, as shown in FIG. 9f, there is a first gap GP1 between at least one side wall of the light-emitting device 120 and the corresponding first reflective portion 133.

For example, there is a first gap GP1 between one side wall or each of side walls of the light-emitting device 120 and the corresponding first reflective portion 133.

Considering an example in which the light-emitting device 120 is in a shape of a rectangle in the top view, there may be a first gap GP1 between one side wall of the light-emitting device 120 and the first reflective portion 133, or there may be a first gap GP1 between each of the four side walls of the light-emitting device 120 and the first reflective portion 133. The first gap GP1 between each of the four side walls and the first reflective portion 133, i.e., the width of the first gap GP1, may be the same or different.

For example, the width of the first gap GP1 is less than or equal to 150 μm.

For example, the width of the first gap GP1 refers to a dimension of the first gap GP1 in a direction perpendicular to the side wall of the corresponding light-emitting device 120.

For example, the width of the first gap GP1 may be 150 μm, 100 μm, 50 μm, 25 μm or 10 μm.

In the embodiments of the present disclosure, the light-emitting substrate 100 is manufactured by the above manufacturing method, which may make the width of the first gap GP1 between the side wall of the light-emitting device 120 and the corresponding first reflective portion 133 in the light-emitting substrate 100 small, thereby improving the area proportion of the reflective layer 130 in the light-emitting substrate 100. As a result, it is possible to improve the luminous efficiency of the light-emitting substrate 100, alleviate the problem of light and dark optical fringes and mura phenomenon of the light-emitting substrate 100, and enhance the luminance of the light-emitting device 120, thereby improving the brightness of the backlight module 10 and the display apparatus 1, and reducing the power consumption of the backlight module 10 and the display apparatus 1.

In some other examples, as shown in FIG. 9f, at least one side wall of the light-emitting device 120 is in contact with the corresponding first reflective portion 133.

For example, one side wall or each of multiple side walls of the light-emitting device 120 is in contact with the corresponding first reflective portion 133.

Considering an example in which of the light-emitting device 120 is in a rectangle in the top view, one side wall of the light-emitting device 120 may be in contact with the first reflective portion 133 (there may be a first gap GP1 between each of the remaining three side walls and the first reflective portion 133); alternatively, all four side walls of the light-emitting device 120 are each in contact with the first reflective portion 133.

In the embodiments of the present disclosure, the light-emitting substrate 100 is manufactured by using the above manufacturing method, which may make the side wall(s) of the light-emitting device 120 in the light-emitting substrate 100 each in contact with the corresponding first reflective portion 133, thereby improving the area proportion of the reflective layer 130 in the light-emitting substrate 100. As a result, it is possible to improve the luminous efficiency of the light-emitting substrate 100, alleviate the problem of light and dark optical fringes and mura phenomenon of the light-emitting substrate 100, thereby improving the luminance of the backlight module 10 and the display apparatus 1, and reducing the power consumption of the backlight module 10 and the display apparatus 1.

In some other examples, as shown in FIG. 9f, there is a first gap GP1 between at least one side wall of the light-emitting device 120 and the corresponding first reflective portion 133, and at least one side wall of the light-emitting device 120 is in contact with the corresponding first reflective portion 133.

For example, one side wall of the light-emitting device 120 is in contact with the corresponding first reflective portion 133, and there is a first gap GP1 between each of the remaining side walls of the light-emitting device 120 and the corresponding first reflective portion 133.

For another example, there is a first gap GP1 between one side wall of the light-emitting device 120 and the corresponding first reflective portion 133, and the remaining side walls of the light-emitting device 120 are each in contact with the corresponding first reflective portion 133.

For another example, as shown in FIG. 9f, there is a first gap GP1 between each of the three side walls of the light-emitting device 120 and the corresponding first reflective portion 133, and the remaining side wall of the light-emitting device 120 is in contact with the corresponding first reflective portion 133.

In the embodiments of the present disclosure, the light-emitting substrate 100 is manufactured by using the above manufacturing method, which may make the side wall(s) of the light-emitting device 120 in the light-emitting substrate 100 are each in contact the corresponding first reflective portion 133 or make each of the side wall(s) of the light-emitting device 120 in the light-emitting substrate 100 and the corresponding first reflective portion 133 have a first gap GP1, thereby improving the area proportion of the reflective layer 130 in the light-emitting substrate 100. As a result, it is possible to improve the luminous efficiency of the light-emitting substrate 100, alleviate the problem of light and dark optical fringes and mura phenomenon of the light-emitting substrate 100, thereby improving the luminance of the backlight module 10 and the display apparatus 1, and reducing the power consumption of the backlight module 10 and the display apparatus 1.

In some examples, as shown in FIG. 15g, the thickness of the first reflective portion 133 is positively correlated with a distance, in a direction Z1 passing through a center O of the light-emitting device 120 and perpendicular to a side wall of the light-emitting device 120, between the first reflective portion 133 and the center of the light-emitting device 120.

Exemplarily, in the sectional view (FIG. 15g) taken along the direction passing through the center of the light-emitting device 120 and perpendicular to the side wall of the light-emitting device 120, the thickness of the first reflective portion 133 is not uniform, and the thickness of the first reflective portion 133 changes with the distance from the first reflective portion 133 to the center of the light-emitting device 120.

As shown in FIG. 15g, the greater a distance between a portion of the first reflective portion 133 and the center of the light-emitting device 120, the greater the thickness of the portion of the first reflective portion 133. The less a distance between a portion of the first reflective portion 133 and the center of the light-emitting device 120, the less the thickness of the portion of the first reflective portion 133. That is, in the direction proximate to the center of the light-emitting device 120 shown in the figure, the thickness of the first reflective portion 133 is gradually reduced, reaching the minimum thickness at the portion closest to the light-emitting device 120.

Exemplarily, the first reflective portion 133 includes a bottom surface 133p and a top surface 133t that are opposite to each other. At least portion of the bottom surface 133p is not in contact with the substrate 110, and an angle between the at least portion of the bottom surface 133p and a plane where the substrate 110 is located is an acute angle. The top surface 133t is parallel to or substantially parallel to the plane where the substrate 110 is located.

For example, an angle between the portion of the bottom surface 133p of the first reflective portion 133 that is not in contact with the substrate 110 and the plane where the substrate 110 is located is an acute angle. In other words, the bottom surface 133p of the first reflective portion 133 is of a structure that is concave inward relative to the top surface 133t.

In some examples, as shown in FIG. 15g, in the direction passing through the center of the light-emitting device 120 and perpendicular to the side wall of the light-emitting device 120, a dimension W4 of the portion of the first reflective portion 133 that is not in contact with the substrate 110 is less than 20 μm.

For example, in the sectional view (FIG. 15g) taken along the direction passing through the center of the light-emitting device 120 and perpendicular to the side wall of the light-emitting device 120, the dimension W4 of the portion of the first reflective portion 133 that is not in contact with the substrate 11 may be 19 μm, 16 μm, 13 μm, 10 μm or 5 μm.

It has been verified by experiments that in a case where the dimension W4 of the portion of the first reflective portion 133 that is not in contact with the substrate 11 is less than 20 μm, it may be ensured that the morphology of the reflective layer 130 meets the optical requirements and the reflectivity of the reflective layer 130 is high.

In some embodiments, a surface of the second reflective portion 134 away from the substrate 110 may be a flat surface or may substantially be a flat surface.

For example, the thickness of the second reflective portion 134 is relatively uniform.

For example, the flat surface may improve the reflectivity of the reflective layer 130.

It can be seen from the above, the top surface of the first reflective portion 133 is parallel to the plane where the substrate 110 is located. Therefore, the top surface of the first reflective portion 133 may be located on the same horizontal plane as the surface of the second reflective portion 134 away from the substrate 110, so that the surface of the reflective layer 130 away from the substrate 110 may be relatively flat, and the first reflective portion 133 and the second reflective portion 134 of the reflective layer 130 may be formed in a single manufacturing process, so as to simplify the manufacturing process of the reflective layer 130.

For example, as shown in FIG. 15g, in a case where a portion of the bottom surface 133p of the first reflective portion 133 is not in contact with the substrate 110, the first reflective portion 133 may be in a shape of a trapezoid in the sectional view. Here, the trapezoid is a non-strictly defined trapezoid.

For another example, in a case where the entire bottom surface 133p of the first reflective portion 133 is not in contact with the substrate 110, the first reflective portion 133 may be in a shape of a triangle in the sectional view. Here, the triangle is a non-strictly defined triangle.

Here, the top surface of the first reflective portion 133 is parallel to or substantially parallel to the plane where the substrate 110 is located, which is a morphological characteristic of the reflective layer 130 formed after a levelling process is performed on the reflective film 136 in the above manufacturing method. Thus, the reflectivity of the top surface of the first reflecting portion 133 may be improved.

For example, a thickness of the reflective layer 130 may be in a range of 55 μm±5 μm. For example, the thickness of the reflective layer 130 is 50 μm, 52 μm, 55 μm, 57 μm or 60 μm.

Considering an example in which the thickness of the reflective layer 130 is 60 μm, the thickness of the first reflective portion 133 may be less than 60 μm. The thickness here refers to the average thickness.

In some embodiments, the minimum thickness of the first reflective portion 133 is less than 60 μm.

For example, the minimum thickness of the first reflective portion 133 may be 59 μm, 55 μm, 50 μm, 45 μm, or 40 μm.

With such the above arrangement, in a case where the first reflective portion 133 is in contact with one side wall of the light-emitting device 120, the proportion of light emitted from the path C may be reduced, thereby avoiding affecting the light extraction effect of the light-emitting device 120.

For cases in which the minimum thicknesses of the first reflective portions 133 are 45 μm and 60 μm, and the widths of the first gaps GP1 each between the first reflective portion 133 and the corresponding light-emitting device 120 are respectively 200 μm, 150 μm, 100 μm, 50 μm, 25 μm, 0 μm, and −15 μm, the luminances of the light-emitting substrates 100 are simulated, and the simulation results are shown in FIG. 11. The above-mentioned “0 μm” represents the case where the first reflective portion 133 is in contact with the light-emitting device 120. The above-mentioned “−15 μm” represents the case where the first reflective portion 133 is in contact with the light-emitting device 120, and a dimension, in the first direction X, of the portion of the first reflective portion 133 covering the light-emitting device 12 is −15 μm. The case in which the minimum thickness of the first reflective portion 133 is 60 μm is equivalent to an implementation in which there is no thickness difference between the first reflective portion and the second reflective portion, and the thickness of the first reflective portion is the same as the thickness of the second reflective portion.

As shown in FIG. 11, considering an example in which the luminance of the light-emitting substrate is 100% in a case where the thickness of the first reflective portion 133 is 60 μm and the light-emitting device 120 is in contact with the first reflective portion 133, as the width of the first gap GP1 is reduced from 150 μm to 0 μm, the luminance is gradually increased, and the fluctuation of the luminance is less than 5%, which is within the acceptable fluctuation range of the luminance; in a case where the width of the first gap GP1 is −15 μm, the luminance is reduced to about 90%, and the luminance fluctuates about 10%, which is within an unacceptable fluctuation range of the luminance. In a case where the width of the first gap GP1 is less than or equal to 150 μm, and the minimum thickness of the first reflective portion 133 is less than 60 μm, the fluctuation of the luminance of the light-emitting substrate 100 is acceptable.

In addition, a computer simulation is performed on the luminance in a case where the width of the first gap GP1 is gradually changed from 300 μm to 0 μm, and FIG. 12 is obtained. In FIG. 12, in a case where the width of the first gap GP1 is 0 μm, the luminance is 100%; in a case where the width of the first gap GP1 is 50 μm, the luminance is 98.9%; in a case where the width of the first gap GP1 is 100 μm, the luminance is 96.5%; in a case where the width of the first gap GP1 is 150 μm, the luminance is 95.0%; in a case where the width of the first gap GP1 is 200 μm, the luminance is 93.4%; in a case where the width of the first gap GP1 is 250 μm, the luminance is 91.6%; in a case where the width of the first gap GP1 is 300 μm, the luminance is 89.7%. In the implementation described above, the large-size light-emitting substrate is manufactured by the method: material preparation→forming the reflective layer by a screen printing process→AOI→die bonding→dot repair→AOI→encapsulation, it is possible to achieve that the gap between the reflective layer and the light-emitting device is in a range of 0.3 mm±0.15 mm (equivalent to the case where the width of the first gap is 300 μm). However, in the embodiments of the present disclosure, the width of the first gap GP1 may reach 0 μm; compared with the implementation, the luminance is increased from 89.7% to 100%, and the luminance gain is approximately 10%; moreover, in the light-emitting substrate 100 formed by the manufacturing method in the above embodiments of the present disclosure, the width of the first gap between the reflective layer 130 and the light-emitting device 120 may be controlled with an accuracy of 0.05 mm±0.05 mm, so that the luminance of the light-emitting substrate 100 may be greatly increased, and the energy consumption of the backlight module 10 and the display apparatus 1 may be reduced.

In some examples, as shown in FIG. 6e, the first reflective portion 133 includes a bottom surface 133p and a top surface 133t that are opposite to each other; the bottom surface 133p is in contact with the substrate 110, and an angle between the top surface 133t and a plane where the substrate 110 is located is an acute angle.

For example, an angle between the portion of the bottom surface 133p of the first reflective portion 133 that is in contact with the substrate 110 and the plane where the substrate 110 is located is an acute angle. That is, the bottom surface 133p of the first reflecting portion 133 is of a structure that protrudes outward relative to the top surface 133t.

For example, the angle α between the top surface 133t and the substrate 110 may be 30°, 35°, 40°, 45° or 50°.

With such the above arrangement, as shown in FIG. 8a, the proportion of light emitted along path C may be small, and the loss of light emitted by the light-emitting device 120 may be small, thereby increasing the reflectivity of the reflective layer 130, improving the luminous efficiency of the light-emitting substrate 100, and reducing the energy consumption of the backlight module 10 and the display apparatus.

In some embodiments, as shown in FIG. 13a, the second reflective portion 134 includes a plurality of protruding structures 135, and the protruding structures 135 has a cambered surface on a side away from the substrate 110.

For example, the cambered surface protrudes outward in a direction away from the substrate 110.

With such the above arrangement, the uniformity of the light emitted by the reflective layer 130 may be improved.

It will be understood that the plurality of protruding structures 135 are unique morphological characteristics of the reflective layer 130 formed by the 3D printing. In the process of using a 3D printing device to print the reflective material to form the second reflective portion 134, multiple printing strips are printed, and two adjacent printing strips partially overlap to form a printing pattern. A portion of each printing strip that does not overlap with the adjacent printing strip forms the protruding structure 135 (the protruding structure 135 here does not include a third protruding structure 135c below).

It will be noted that the extending direction and arrangement of the protruding structures 135 are mainly determined by the printing path of the 3D printing process.

For example, as shown in FIG. 13a, in a case where the printing direction of the printing path of the 3D printing process in the above manufacturing method is the first direction X, the plurality of protruding structures 135 each extend in the first direction X and are arranged in multiple rows in the second direction Y.

For example, in a case where the printing direction of the printing path of the 3D printing process is the second direction Y, the plurality of protruding structures 135 each extend in the second direction Y and are arranged in multiple columns in the first direction X.

In some examples, as shown in FIG. 13b, the protruding structures 135 include a plurality of first protruding structures 135a and a plurality of second protruding structures 135b.

For example, the plurality of first protruding structures 135a and the plurality of second protruding structures 135b may extend and may be arranged in various ways.

For example, as shown in FIG. 13b, the extending direction of the plurality of first protruding structures 135a and the extending direction of the plurality of second protruding structures 135b may be the same. The plurality of first protruding structures 135a each extend in the first direction X and are arranged in multiple rows in the second direction Y; the plurality of second protruding structures 135b each extend in the first direction X and are arranged in multiple rows in the second direction Y.

For another example, the extending direction of the plurality of first protruding structures 135a and the extending direction of the plurality of second protruding structures 135b may be different. The plurality of first protruding structures 135a each extend in the first direction X and are arranged in multiple rows in the second direction Y; the plurality of second protruding structures 135b each extend in the second direction Y and are arranged in multiple rows in the first direction X.

For example, the first protruding structure 135a may be a protruding structure formed by using a printing process in a straight-line manner, and the second protruding structure 135b may be a protruding structure formed by using a printing process in a dotted-line manner.

For example, a dimension of the first protruding structure 135a in the second direction Y is the same as a dimension of the second protruding structure 135b in the arrangement direction of the plurality of second protruding structures 135b. That is, a width of a portion of each printing strip, formed by using the printing process in a straight-line manner, that does not overlap with the adjacent printing strip is the same as a width of a portion of each printing strip, formed by using the printing process in a dotted-line manner, that does not overlap with the adjacent printing strip.

In some embodiments, as shown in FIG. 13c, the plurality of protruding structures 135 further include third protruding structures 135c each located between two adjacent first protruding structures 135a; the third protruding structure 135c extends in the first direction X.

Exemplarily, the plurality of third protruding structures 135c are arranged in multiple rows in the second direction Y.

For example, the extending direction of the third protruding structure 135c is the same as the extending direction of the first protruding structure 135a that is adjacent to the third protruding structure 135c.

In some examples, a dimension W3 of the third protruding structure 135c in the second direction Y is less than a dimension W1 of the first protruding structure 135a in the second direction Y.

For example, the third protruding structure 135c is formed at the overlapping position of two adjacent printing strips. Therefore, the dimension W3 of the third protruding structure 135c in the second direction Y is much less than the dimension W1 of the first protruding structure 135a in the second direction Y.

In some embodiments, as shown in FIG. 14d, in a case where the first reflective portion 133 surrounds the light-emitting device 120, and the orthographic projection of the light-emitting device 120 on the substrate 110 is in a shape of a rectangle, the light-emitting device 120 includes a first side wall 120a1, a second side wall 120b, a third side wall 120c and a fourth side wall 120e that are connected in sequence; the first side wall and the third side wall are opposite to each other and each extend in the first direction X; the second side wall and the fourth side wall are opposite to each other, and each extend in the second direction Y; the first reflective portion 133 includes a first reflective sub-portion 133a located on a side of the first side wall 120a1, a second reflective sub-portion 133b located on a side of the second side wall 120b, and a third reflective sub-portion 133c located on a side of the third side wall 120c, and a fourth reflective sub-portion 133e located on a side of the fourth side wall 120e.

For example, the first reflective portion 133 is in a shape of a rectangle in the top view. The center of the rectangle may or may not coincide with the center of the orthographic projection of the light-emitting device 120 on the substrate 110.

For example, the first side wall may be substantially parallel to the first reflective sub-portion 133a; the second side wall may be substantially parallel to the second reflective sub-portion 133b; the third side wall may be substantially parallel to the third reflective sub-portion 133c; the fourth side wall may be substantially parallel to the fourth reflective sub-portion 133e.

In some examples, multiple first reflective sub-portions 133a located on a side of the first side walls of the light-emitting devices 120 in a row are connected to form a one-piece structure. The multiple first reflective sub-portions 133a of the one-piece structure are formed by one fifth reflective pattern RP5. With such the above arrangement, the multiple first reflective sub-portions 133a located on a side of the first side walls of the light-emitting devices 120 in a row may be formed in a single manufacturing process, which is beneficial to simplifying the manufacturing process of the light-emitting substrate 100.

In some examples, multiple second reflective sub-portions 133b located on a side of the second side walls of the light-emitting devices 120 in a column are connected to form a one-piece structure. The multiple first reflective sub-portions 133a of the one-piece structure are formed by one sixth reflective pattern RP6. With such the above arrangement, the multiple second reflective sub-portions 133b located on a side of the second side walls of the light-emitting devices 120 in a column may be formed in a single manufacturing process, which is beneficial to simplifying the manufacturing process of the light-emitting substrate 100.

In some examples, multiple third reflective sub-portions 133c located on a side of the third side walls of the light-emitting devices 120 in a row are connected to form a one-piece structure. The multiple third reflective sub-portions 133c of the one-piece structure are formed by one fifth reflective pattern RP5. With such the above arrangement, the multiple third reflective sub-portions 133c located on a side of the third side walls of the light-emitting devices 120 in a row may be formed in a single manufacturing process, which is beneficial to simplifying the manufacturing process of the light-emitting substrate 100.

In some examples, multiple fourth reflective sub-portions 133e located on a side of the fourth side walls of the light-emitting devices 120 in a column are connected to form a one-piece structure. The multiple first reflective sub-portions 133a of the one-piece structure are formed by one sixth reflective pattern RP6. With such the above arrangement, the multiple fourth reflective sub-portions 133e located on a side of the fourth side walls of the light-emitting devices 120 in a column may be formed in a single manufacturing process, which is beneficial to simplifying the manufacturing process of the light-emitting substrate 100.

In some embodiments, as shown in FIG. 18e, in a case where the first reflective portion 133 surrounds the light-emitting device 120, the reflective layer 130 further includes third reflective portions 137 each located between a first reflective portion 133 and a second reflective portion 134. The second reflective portion 134 is connected to the first reflective portion 133 through the third reflective portion 137. The third reflective portion 137 surrounds the first reflective portion 133, and a thickness of the third reflective portion 137 is less than a thickness of the first reflective portion 133.

For example, the thickness of the first reflective portion 133 may be 50 μm, the thickness of the third reflective portion 137 may be 45 μm, and the thickness of the second reflective portion 134 may be 55 μm.

The thickness of the first reflective portion 133 refers to the maximum thickness of the first reflective portion 133.

It will be understood that, the thickness relationship between the first reflective portion 133 results in the morphological characteristic of the “coffee ring” in the reflective layer 130 around the light-emitting device 120, and the morphological characteristic of the “coffee ring” in the reflective layer 130 are the unique morphology of the reflective layer formed by the manufacturing method provided in the embodiments of the present disclosure.

For example, a “coffee ring” visible to the human eye (as shown in FIG. 18g) is formed at the edge (the region enclosed by the dotted circle in FIG. 18f) of the first reflective portion 133. That is, for the first reflective layer 130, the thickness of a portion (i.e., the third reflective portion 137) in a certain region around the first reflective portion 133 is less than the thickness of the first reflective portion 133, and the difference between the thicknesses is approximately 10 μm.

It will be understood that, as shown in FIGS. 19a and 19b, the light-emitting substrate 100 further includes a plurality of driver chips 170.

In some examples, a driver chip 170 is electrically connected to at least one light-emitting device 120, and the driver chip 170 is configured to drive the at least one light-emitting device 120 to emit light.

For example, a driver chip 170 is electrically connected to a light-emitting device 120 to drive the light-emitting device 120 to emit light.

For example, a driver chip 170 is electrically connected to four light-emitting devices 120 to drive the four light-emitting devices 120 to emit light.

For example, a driver chip 170 is electrically connected to nine light-emitting devices 120 to drive the nine light-emitting devices 120 to emit light.

The description will be made by taking an example in which a driver chip 170 drives four light-emitting devices 120.

There are two relative positional relationships between the driver chips 170 and the reflective layer 130, i.e., the driver chip(s) 170 are located in respective openings 131, and the driver chip(s) 170 are covered by the reflective layer 130. The light-emitting substrates 100 corresponding to the above two positional relationships respectively will be manufactured by different manufacturing methods, which will be described separately below.

In some embodiments, as shown in FIG. 19b, the plurality of openings 131 of the reflective layer 130 further include a plurality of second opening 131b.

In some examples, the plurality of driver chips 170 are in one-to-one correspondence with the plurality of second openings 131b, and a driver chip 170 is located in a second opening 131b.

For example, the size of the first opening 131a is related to the size of the light-emitting device 120, and the size of the second opening 131b is related to the size of the driver chip 170. Therefore, the size of the first opening 131a and the size of the second opening 131b may be the same or different. The shape of the first opening 131a in the top view may be the same as or different from the shape of the second opening 131b in the top view.

For example, the first reflective portion 133 is located on at least one side of the driver chip 170.

In some examples, the first reflective portion 133 is located on at least one side of the driver chip 170 in various manners. For example, the first reflective portion 133 may be located on a side of the driver chip 170. For another example, the first reflective portion 133 may be located on two adjacent sides or two opposite sides of the driver chip 170. For another example, the first reflective portion 133 may surround the corresponding driver chip 170.

In the above embodiment, as shown in FIG. 19c, at least one side wall of the driver chip 170 is in contact with the corresponding first reflective portion 133, and/or at least one side wall of the driver chip 170 and the corresponding first reflective portion 133 have a second gap GP2 therebetween.

In some examples, at least one side wall of the driver chip 170 is in contact with the corresponding first reflective portion 133.

For example, one side wall or multiple side walls of the driver chip 170 are each in contact with the corresponding first reflective portion 133.

Considering an example in which the driver chip 170 is in a shape of a rectangle in the top view, one side wall of the driver chip 170 is in contact with the first reflective portion 133 (each of the other three side walls and the first reflective portion 133 may have a second gap therebetween), or four side walls of the driver chip 170 are each in contact with the first reflecting portion 133.

In the embodiments of the present disclosure, the light-emitting substrate 100 is manufactured by using the above manufacturing method, the portion of the substrate 110 located around each driver chip 170 is cleaned, which alleviates the repelling phenomenon occurring between the portion of the substrate located around the driver chip 170 and the reflective material that needs to be printed in the subsequent process, so that the side wall of the driver chip 170 is in contact with the corresponding first reflective portion 133 in the light-emitting substrate 100. As a result, it is possible to increase the area proportion of the reflective layer 130 in the light-emitting substrate 100, which may improve the luminous efficiency of the light-emitting substrate 100, and alleviate the problem of light leakage, light and dark optical fringes, and mura phenomenon of the light-emitting substrate 100, thereby improving the luminance of the backlight module 10 and the display apparatus 1, and reducing the power consumption of the backlight module 10 and the display apparatus 1.

In some other examples, there is a second gap GP2 between at least one side wall of the driver chip 170 and the corresponding first reflective portion 133.

For example, there is a second gap GP2 between one side wall or each of multiple side walls of the driver chip 170 and the corresponding first reflective portion 133.

Considering an example in which the driver chip 170 is in a shape of a rectangle in the top view, there may be a second gap GP2 between one side wall of the driver chip 170 and the first reflective portion 133; alternatively, there may be a second gap GP2 between each of the four side walls of the driver chip 170 and the first reflective portion 133, and the distance between each of the four side walls and the first reflective portion 133 is the same.

For example, the width of the second gap GP2 is less than or equal to 150 μm.

For example, the width of the second gap GP2 refers to a dimension of the second gap GP2 in a direction perpendicular to the side wall of the corresponding light-emitting device 120.

For example, the width of the second gap GP2 may be 150 μm, 100 μm, 50 μm, 25 μm or 10 μm.

It will be understood that the width of the second gap GP2 and the width of the first gap GP1 may be the same or different.

In the embodiments of the present disclosure, the light-emitting substrate 100 is manufactured by using the above manufacturing method, the portion of the substrate 110 located around each driver chip 170 is cleaned, which alleviates the repelling phenomenon occurring between the portion of the substrate located around the driver chip 170 and the reflective material that needs to be printed in the subsequent process, so that the width of the second gap between the side wall of the driver chip 170 and the corresponding first reflective portion 133 in the light-emitting substrate 100 is small. As a result, it is possible to increase the area proportion of the reflective layer 130 in the light-emitting substrate 100, which may improve the luminous efficiency of the light-emitting substrate 100, and alleviate the problem of light and dark optical fringes and mura phenomenon of the light-emitting substrate 100, thereby improving the luminance of the backlight module 10 and the display apparatus 1, and reducing the power consumption of the backlight module 10 and the display apparatus 1.

In some other examples, at least one side wall of the driver chip 170 is in contact with the corresponding first reflective portion 133, and there is a second gap GP2 between another at least one side wall of the driver chip 170 and the corresponding first reflective portion 133.

For example, one side wall of the driver chip 170 is in contact with the corresponding first reflective portion 133, and there is a second gap GP2 between each of the remaining side walls of the driver chip 170 and the corresponding first reflective portion 133.

For another example, there is a second gap GP2 between one side wall of the driver chip 170 and the corresponding first reflecting portion 133, and the remaining side walls of the driver chip 170 are each in contact with the corresponding first reflecting portion 133.

For another example, there is a second gap GP2 between each of two side walls of the driver chip 170 and the corresponding first reflecting portion 133, and the remaining side walls of the driver chip 170 are each in contact with the corresponding first reflecting portion 133.

In the embodiments of the present disclosure, the light-emitting substrate 100 is manufactured by using the above manufacturing method, the portion of the substrate 110 located around each driver chip 170 is cleaned, which alleviates the repelling phenomenon occurring between the portion of the substrate located around the driver chip 170 and the reflective material that needs to be printed in the subsequent process, so that the side wall(s) of the driver chip 170 in the light-emitting substrate 100 are each in contact with the corresponding first reflective portion 133 or there is a second gap with a small width between each of the side wall(s) of the driver chip 170 and the corresponding first reflective portion 133 in the light-emitting substrate 100. As a result, it is possible to increase the area proportion of the reflective layer 130 in the light-emitting substrate 100, which may improve the luminous efficiency of the light-emitting substrate 100 and alleviate the problem of light and dark optical fringes and mura phenomenon of the light-emitting substrate 100, thereby improving the luminance of the backlight module 10 and the display apparatus 1 and reducing the power consumption of the backlight module 10 and the display apparatus 1.

As shown in FIG. 19d, for the case where the driver chip(s) 170 are covered by the reflective layer 130, which may include the case in which an orthographic projection of at least one driver chip 170 on the substrate 110 is located within the orthographic projection of the reflective layer 130 on the substrate 110. That is, at least one driver chip 170 is covered by the reflective layer 130, and the remaining driver chips 170 may be located in the respective second openings 131b of the reflective layer 130.

For example, a border of an orthographic projection of a driver chip 170 on the substrate 110 is within the border of the orthogonal projection of the reflective layer 130 on the substrate 110.

For another example, the borders of the orthographic projections of the plurality of driver chips 170 on the substrate 110 are all within the border of the orthographic projection of the reflective layer 130 on the substrate 110.

With such the above arrangement, the area proportion of the reflective layer 130 in the light-emitting substrate 100 may be increased, and the area of the reflective region of the light emitted by the light-emitting device 120 may be increased, thereby improving the luminous efficiency of the light-emitting substrate 100 and alleviating the problem of light leakage of the light-emitting substrate 100.

It will be understood that, as for the structural features of the reflective layer 130 and the light-emitting substrate 100 in the case where the driver chip 170 is located in the second opening 131b and the first reflective portion 133 is located on at least one side of the driver chip 170, reference will be made to the structural features that the first reflective portion 133 is located on at least one side of the light-emitting device 120, which will not be repeated here.

In some embodiments, as shown in FIG. 3, the light-emitting substrate 100 further includes bonding structures 180. The bonding structure 180 is electrically connected to, for example, the driver chip 170.

For example, the bonding structures 180 are located on a region of the light-emitting substrate 100 proximate to the edge of the light-emitting substrate 100. The bonding structure 180 is used to transmit different types of working signals to the driver chip 170, so that the driver chip 170 generates a driving signal according to the different types of working signals and transmits the driving signal to the corresponding light-emitting device(s) 120.

For example, the region where the bonding structure 180 is located is not covered by the reflective layer 130.

For example, the bonding structure 180 may be bonded to PCB or a flexible printed circuit (FPC) by chip on film (COF).

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting substrate comprising: a substrate, a plurality of light-emitting devices and a reflective layer that are disposed on a side of the substrate;
wherein the reflective layer has a plurality of openings, the plurality of openings include a plurality of first openings, and a light-emitting device of the plurality of light-emitting devices is located in a first opening of the plurality of first openings; and
the reflective layer includes a plurality of first reflective portions and a second reflective portion connecting any two adjacent first reflective portions; a first reflective portion, corresponding to the light-emitting device, of the plurality of first reflective portions is located on at least one side of the light-emitting device; a thickness of the first reflective portion is less than a thickness of the second reflective portion.

2. The light-emitting substrate according to claim 1, wherein the first reflective portion is located on two opposite sides of the light-emitting device, or the first reflective portion surrounds the light-emitting device.

3. The light-emitting substrate according to claim 2, wherein the first reflective portion is located on the two opposite sides of the light-emitting device, an orthographic projection of the light-emitting device on the substrate is in a shape of a rectangle, and the first reflective portion is located on sides of two long sides of the rectangle.

4. The light-emitting substrate according to claim 1, wherein at least one side wall of the light-emitting device and the corresponding first reflective portion have a first gap therebetween.

5. The light-emitting substrate according to claim 4, wherein a width of the first gap is less than or equal to 150 μm.

6. The light-emitting substrate according to claim 1, wherein at least one side wall of the light-emitting device is in contact with the corresponding first reflective portion.

7. The light-emitting substrate according to claim 1, wherein the thickness of the first reflective portion is positively correlated with a distance, in a direction passing through a center of the light-emitting device and perpendicular to a side wall of the light-emitting device, between the first reflective portion and the center of the light-emitting device; and
the first reflective portion includes a bottom surface and a top surface that are opposite to each other, the bottom surface is in contact with the substrate, and an angle between the top surface and a plane where the substrate is located is an acute angle.

8. The light-emitting substrate according to claim 7, wherein a minimum thickness of the first reflective portion is less than 60 μm.

9. The light-emitting substrate according to claim 1, wherein the thickness of the first reflective portion is positively correlated with a distance, in a direction passing through a center of the light-emitting device and perpendicular to a side wall of the light-emitting device, between the first reflective portion and the center of the light-emitting device; and
the first reflective portion includes a bottom surface and a top surface that are opposite to each other; at least portion of the bottom surface is not in contact with the substrate, and an angle between the at least portion of the bottom surface and a plane where the substrate is located is an acute angle; the top surface parallel to or substantially parallel to the plane where the substrate is located.

10. The light-emitting substrate according to claim 9, wherein in the direction passing through the center of the light-emitting device and perpendicular to the side wall of the light-emitting device, a dimension of a portion of the first reflective portion that is not in contact with the substrate is less than 20 μm.

11. The light-emitting substrate according to claim 9, wherein a surface of the second reflective portion away from the substrate is a flat surface or an approximately flat surface.

12. The light-emitting substrate according to claim 1, wherein the second reflective portion includes a plurality of protruding structures, and a protruding structure of the plurality of protruding structures has a cambered surface on a side away from the substrate.

13. The light-emitting substrate according to claim 12, wherein the plurality of protruding structures include a plurality of first protruding structures and a plurality of second protruding structures; wherein
the plurality of first protruding structures each extend in a first direction and are arranged in rows in a second direction;
the plurality of second protruding structures each extend in the first direction and are arranged in rows in the second direction, or the plurality of second protruding structures each extend in the second direction and are arranged in rows in the first direction; the first direction intersects with the second direction; and
a dimension of a first protruding structure of the plurality of first protruding structures in the second direction is same as a dimension of a second protruding structure of the plurality of second protruding structures in an arrangement direction of the plurality of second protruding structures.

14. The light-emitting substrate according to claim 13, wherein the plurality of protruding structures further includes a third protruding structure located between two adjacent first protruding structures, the third protruding structure extends in the first direction; wherein
a dimension of the third protruding structure in the second direction is less than a dimension of the first protruding structure in the second direction.

15. The light-emitting substrate according to claim 1, wherein the first reflective portion surrounds the light-emitting device, the reflective layer further includes a third reflective portion located between the first reflective portion and the second reflective portion; the second reflective portion is connected to the first reflective portion through the third reflective portion, the third reflective portion surrounds the first reflective portion, and a thickness of the third reflective portion is less than the thickness of the first reflective portion.

16. The light-emitting substrate according to claim 1, wherein the plurality of light-emitting devices are arranged in columns in a first direction and arranged in rows in a second direction, the first direction intersects with the second direction;
the first reflective portion surrounds the light-emitting device and an orthographic projection of the light-emitting device on the substrate is in a shape of a rectangle, the light-emitting device includes a first side wall, a second side wall, a third side wall and a fourth side wall that are connected in sequence; the first side wall is opposite to the third side wall and extends in the first direction; the second side wall is opposite to the fourth side wall and extends in the second direction; the first reflective portion includes a first reflective sub-portion located on a side of the first side wall, a second reflective sub-portion located on a side of the second side wall, a third reflective sub-portion located on a side of the third side wall, and a fourth reflective sub-portion located on a side of the fourth side wall; wherein
a plurality of first reflective sub-portions located on a side of first side walls of light-emitting devices in a row are connected to form a one-piece structure;
a plurality of second reflective sub-portions located on a side of second side walls of the light-emitting devices in the row are connected to form a one-piece structure;
a plurality of third reflective sub-portions located on a side of third side walls of the light-emitting devices in the row are connected to form a one-piece structure; and
a plurality of fourth reflective sub-portions located on a side of fourth side walls of the light-emitting devices in the row are connected to form a one-piece structure.

17. The light-emitting substrate according to claim 1, further comprising: a plurality of driver chips disposed on a side of the substrate and located on a same side of the substrate as the plurality of light-emitting devices; wherein a driver chip of the plurality of driver chips is electrically connected to at least one light-emitting device of the plurality of light-emitting devices, and the driver chip is configured to drive the at least one light-emitting device to emit light; wherein
the plurality of openings further include a plurality of second openings; the driver chip is located in a second opening, and a first reflective portion, corresponding to the driver chip, of the plurality of first reflective portions is located on at least one side of the driver chip.

18. The light-emitting substrate according to claim 17, wherein at least one side wall of the driver chip is in contact with the corresponding first reflective portion, and/or the at least one side wall of the driver chip and the corresponding first reflective portion have a second gap therebetween.

19. The light-emitting substrate according to claim 1, further comprising: a plurality of driver chips disposed on a side of the substrate and located on a same side of the substrate as the plurality of light-emitting devices; wherein a driver chip is electrically connected to at least one light-emitting device, and the driver chip is configured to drive the at least one light-emitting device to emit light; an orthographic projection of at least one driver chip on the substrate is located within an orthographic projection of the reflective layer on the substrate.

20-27. (canceled)

28. A backlight module, comprising: the light-emitting substrate according to claim 1, and an optical film disposed on a light exit side of the light-substrate.

29. (canceled)
